(19) United States
(12) Patent Application Publication
(10) Pub. No.: US 2003/0011025 A1
(43) Pub. Date: Jan. 16, 2003

(54) Nonvolatile semiconductor memory device and manufacturing method thereof

(75) Inventor: Naoki Tsuji, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/135,457

(22) Filed: May 1, 2002

(30) Foreign Application Priority Data
Jul. 12, 2001 (JP) 2001-211803(P)

(51) Int. Cl. H01L 29/788

(52) U.S. Cl. 257/316

(57) ABSTRACT

On a cross section along a region put between word lines, trench isolation oxide films are formed on a surface of a semiconductor substrate and source lines and bit lines are formed in an element formation region put between the trench isolation oxide films. A thick insulating film is formed on the source lines, the bit lines and the trench isolation oxide films. A recess is formed in a region of the semiconductor substrate located between the source line and the bit line. As a result, a nonvolatile semiconductor memory device capable of reducing a capacitance between a floating gate electrode and the semiconductor substrate is obtained.

### BACKGROUND OF THE INVENTION

1. Field of the Invention

The present invention relates to a nonvolatile semiconductor memory device and a manufacturing method thereof. The present invention particularly relates to a nonvolatile semiconductor memory device and a nonvolatile semiconductor memory device capable of reducing parasitic capacitance.

2. Description of the Background Art

As one example of conventional nonvolatile semiconductor memories, a flash memory will be described. As shown in FIG. 37, a source line 103a and a bit line (a drain) 103b are formed away from each other in the element formation region of a semiconductor substrate formed by trench isolation regions 102. A floating gate electrode 105 (see FIG. 38) is formed in the region of the semiconductor substrate put between source line 103a and bit line 103b. A word line 108 is formed on the floating gate electrode 105.

Next, a cross-sectional structure along each sectional line shown in FIG. 37 will be described. First, as shown in FIG. 38, on a cross section (cross-sectional line XXXVIII-XXXVIII) along word line 108, trench isolation oxide films 102 are formed on the surface of semiconductor substrate 101 and source line 103a and bit line 103b are formed in the element formation region put between trench isolation oxide films 102.

A thick insulating film 106 is formed on source line 103a, bit line 103b and trench isolation oxide films 102. Floating gate electrode 105 is formed on the surface of semiconductor substrate 101 put between source line 103a and bit line 103b with a tunnel oxide film 104 interposed.

Word line 108 consisting of a polysilicon film 109 and a tungsten silicide film 110 is formed on floating gate electrode 105 with an ONO film 107 interposed. It is noted that the ONO film is a film formed by building up a silicon oxide film and a silicon nitride film. An insulating film 111 is formed on word line 108. In the flash memory, memory cell transistors (Tr1, Tr2 and the like) shown in FIG. 37 are each constituted to include source line 103a, bit line 103b, floating gate electrode 105 and word line 108.

Next, as shown in FIG. 39, on a cross section (a cross-sectional line XXXIX-XXXIX) along the region put between word lines 108, trench isolation oxide regions 102 are formed on the surface of semiconductor substrate 101 and source line 103a and bit line 103b are formed in the element formation region put between trench isolation oxide films 102.

Next, as shown in FIG. 40, on a cross section (a cross-sectional line XL-XL) along the region put between source line 103a and bit line 103b, floating gate electrodes 105 are formed on the surface of semiconductor substrate 101 with tunnel oxide films 104 interposed. Word lines 108 each consisting of polysilicon film 109 and tungsten silicide film 110 are formed on floating gate electrodes 105 with ONO films 107 interposed, respectively. Insulating films 111 such as silicon oxide films are formed on respective word lines 108. The conventional flash memory is constituted as stated above. In FIGS. 38 to 40, an interlayer insulating film covering word lines 108 is not shown.

Next, the operation of the flash memory stated above will be described. In case of, for example, reading information of transistor Tr2 shown in FIG. 37, the level of electrons stored in floating gate electrode 105 is determined depending on whether transistor Tr2 is turned on when a predetermined voltage is applied to bit line 103b and a predetermined voltage is applied to word line 108 constituting transistor Tr2.

If transistor Tr2 is turned on, a current flows through Tr2 as indicated by an arrow shown in FIG. 37. In this flash memory, a plurality of transistors Tr1, Tr2 and the like are connected in parallel between source line 103a and bit line 103b, for example. This flash memory is particularly referred to as “AND type flash memory”.

As the conventional flash memories, a NAND type flash memory in which transistors forming memory cells are connected in series is used besides the above-stated AND type flash memory.

The above-stated AND type flash memory and the NAND type flash memory have, however, the following disadvantages. In case of not only AND type and NAND type flash memories but also a so-called stack type flash memory, the ratio among the capacitance 121 (Ccg) between word line (control gate electrode) 108 and floating gate electrode 105 and capacitances 122 and 120 (Cb and Cs) between floating gate electrode 105 and semiconductor substrate 101 as shown in FIG. 40 is important.

It is noted that capacitance Cb is capacitance (tunnel region capacitance) 122 between the lower surface portion of floating gate electrode 105 and the region (channel region) of semiconductor substrate 101 located right under the lower surface portion of floating gate electrode 105 and that capacitance Cs is capacitance 120 between the side surface portion of floating gate electrode 105 and the region of semiconductor substrate 101 located below the side surface portion of floating gate electrode 105.

This ratio is particularly referred to as the coupling ratio of control gate electrode 108 to floating gate electrode 105 and defined by a formula Ccg/(Ccg+Cb+Cs). If the value of this coupling ratio is higher, the operating voltage of a memory cell can be made lower and the performance of the flash memory can be improved.

If the size of a memory cell is relatively large, tunnel region capacitance 122 is sufficiently higher than capacitance 120 among the capacitances between floating gate electrode 105 and semiconductor substrate 101 and, therefore, dominant.

If the size of the memory cell becomes smaller, however, tunnel region capacitance Cb 122 becomes lower. Due to this, capacitance Cs120 cannot be ignored relatively to tunnel region capacitance Cb122, disadvantageously preventing the further improvement of the performance of the flash memory.

### SUMMARY OF THE INVENTION

The present invention has been made to solve the above-stated disadvantages. It is one object of the present invention to provide a nonvolatile semiconductor memory device capable of reducing the capacitance between a floating gate electrode and a semiconductor substrate. It is another object of the present invention to provide a method for manufacturing the nonvolatile semiconductor memory device.

A nonvolatile semiconductor memory device in one aspect of the present invention includes a region becoming a predetermined channel, the first electrode section, the second electrode section, recesses, a pair of impurity regions of the second conductive type. The region becoming the predetermined channel is formed on the main surface of a semiconductor substrate of the first conductive type. The first electrode section is formed on the region becoming the channel with the first insulating film interposed and the first electrode section has a bottom surface, side surfaces and an upper surface. The second electrode section is formed on the upper surface of the first electrode section with the second insulating film interposed. The recesses are formed in one region and the other region of the semiconductor substrate, sandwiching the region becoming the channel. The pair of impurity regions of the second conductive type are formed at regions sandwiching the region becoming the channel. The third insulating film is formed on the semiconductor substrate to embed the recesses.

According to this constitution, the distance between the side surface of the first electrode section and the semiconductor substrate on the side on which each recess is formed is made longer. Consequently, among the capacitances between the first electrode section and the regions of the semiconductor substrate, the capacitance (capacitance Cs) between the side surface portion of the first electrode section and the region of the semiconductor substrate located below the side surface portion thereof can be made lower and capacitance Cs can be made low relatively to the capacitance (tunnel region capacitance Cb) between the bottom of the first electrode section and the region of the semiconductor substrate located right below the bottom of the first electrode section, as compared with the conventional nonvolatile semiconductor memory device. As a result, the coupling capacitance ratio of the nonvolatile semiconductor memory device can be improved compared with that of the conventional flash memory and the performance of the nonvolatile semiconductor memory device can be thereby improved. It is noted that the coupling capacitance ratio is a ratio of the capacitance (Ccg) between the second electrode section and the first electrode section to the sum of the capacitance (Cb+Cs) between the first electrode section and the semiconductor substrate and capacitance Ccg. It is said that the higher the value of the coupling capacitance ratio is, the better the performance of the nonvolatile semiconductor memory device becomes.

To be specific, it is preferable that the pair of impurity regions are formed at the semiconductor substrate in a direction almost orthogonal to a direction coupling the one region and the other region.

A nonvolatile semiconductor memory device referred to as a so-called AND type nonvolatile semiconductor memory device is thus constituted.

In particular, the pair of impurity regions extend along the direction coupling the one region and the other region to sandwich the recesses, whereby the paired impurity regions become wirings, i.e., a source line and a bit line (drain), respectively.

Further, it is preferable that impurities of the first conductive type are introduced into the surfaces of the recesses.

By doing so, a region in which the impurities of the first conductive type are introduced is located between the paired impurity regions of the second conductive type, making it possible to suppress a leak current between the paired impurity regions.

It is also preferable that to suppress a leak current, the recesses are formed deeper than portions on which the pair of impurity regions are located, respectively.

Moreover, it is preferable that the nonvolatile semiconductor memory device includes the first mask material and the second mask material formed on the pair of impurity regions and the upper surface of the second electrode section, respectively, and each having an insulating property to become a mask for forming the recesses.

The recesses can be thereby formed in a self-aligned manner while using the first mask member and the second mask member as a mask.

It is preferable that each of the first mask material and the second mask material includes a silicon oxide film.

Alternatively, it is preferable that the pair of impurity regions are formed on the surfaces of the recesses, respectively and that element isolation insulating films are formed at the semiconductor substrate in a direction almost orthogonal to a direction coupling the one region and the other region.

In this case, a so-called NAND type nonvolatile semiconductor memory device is constituted.

Additionally, in this case, the nonvolatile semiconductor memory device preferably includes a mask material formed on the upper surface of the second electrode section and having an insulating property to become a mask for forming the recesses together with the element isolation insulating films.

The recesses can be thereby formed in a self-aligned manner while using the mask member and the element isolation insulating films as a mask.

It is preferable that each of the mask material and the element isolation insulating film includes a silicon oxide film.

A manufacturing method of a nonvolatile semiconductor memory device in another aspect of the present invention includes the following steps. The first conductive layer is formed on the main surface of a semiconductor substrate of the first conductive type to extend in one direction with the first insulating film interposed. The second conductive layer is formed on the first conductive layer with the second insulating film interposed. A predetermined mask member is formed on the second conductive layer. The second conductive layer is processed while using the predetermined mask member as a mask, thereby forming at least two upper electrode sections extending in a direction almost orthogonal to the one direction. Further, the first conductive layer is processed while using the predetermined mask member as a mask, thereby exposing the surface of the semiconductor substrate and forming lower electrode sections located right below the at least two upper electrode sections, respectively. A pair of impurity regions of the second conductive type are formed at first surface regions of the semiconductor substrate sandwiching the lower electrode sections. Recesses are formed at second surface regions of the semiconductor substrate sandwiching the lower electrode sections. The third insulating film is formed on the semiconductor substrate to embed the recesses.

According to this manufacturing method, the recesses are formed at the second surface regions of the semiconductor substrate sandwiching the region of the substrate located right below the lower electrode section and becoming the channel, whereby the distance between the side surface of the lower electrode section and the semiconductor substrate on the side on which each recess is formed is made longer. Consequently, as stated above, among the capacitances between the lower electrode section and the regions of the semiconductor substrate, the capacitance (capacitance Cs) between the side surface portion of the lower electrode section and the region of the semiconductor substrate located below the side surface portion thereof can be made lower and capacitance Cs can be made low relatively to the capacitance (tunnel region capacitance Cb) between the bottom of the lower electrode section and the region of the semiconductor substrate located right below the bottom of the lower electrode section, as compared with the conventional nonvolatile semiconductor memory device. As a result, the coupling capacitance ratio of the nonvolatile semiconductor memory device can be improved compared with that of the conventional flash memory and the performance of the nonvolatile semiconductor memory device can be thereby improved.

To be specific, it is preferable that in the step of forming the pair of impurity regions, the first conductive layer is formed and then the pair of impurity regions are formed along the first conductive layer in the first surface regions sandwiching the first conductive layer; the manufacturing method preferably includes a step of forming a fourth insulating film on the pair of impurity regions after forming the pair of impurity regions and before forming the second conductive layer; and that in the step of forming the recesses, the recesses are formed by processing the second surface regions put between the two upper electrode sections and put between the pair of impurity regions, respectively while using the predetermined mask member and the fourth insulating film as the mask.

The recesses can be thereby easily formed in a self-aligned manner in a so-called AND type nonvolatile semiconductor memory device.

It is also preferable that the manufacturing method of a nonvolatile semiconductor memory device includes a step of introducing impurities of the first conductive type into surfaces of the recesses after forming the recesses.

By doing so, a region in which the impurities of the first conductive type are introduced is located between the paired impurity regions of the second conductive type, making it possible to suppress a leak current between the paired impurity regions.

Furthermore, it is preferable that in the step of forming the recesses, the recesses are formed deeper than portions in which the pair of impurity regions are located, respectively so as to suppress the leak current.

Alternatively, it is preferable that the manufacturing method includes a step of, after the step of forming the first conductive layer, forming element isolation insulating films in the one region and the other region of the semiconductor substrate located to put the first conductive layer between the one region and the other region, respectively along a direction in which the first conductive layer extends; in the step of forming the recesses, the recesses are formed by processing the second surface regions put between the two upper electrode sections and put between the element isolation insulating films while using the predetermined mask member and the element isolating insulating films as the mask; and that in the step of forming the pair of impurity regions, the pair of impurity regions are formed on surfaces of the recesses.

In this case, it is possible to easily form the recesses in a self-aligned manner in a so-called NAND type semiconductor memory device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a flash memory as a nonvolatile semiconductor memory device in the first embodiment according to the present invention;

FIG. 2 is a cross-sectional view taken along line II-II shown in FIG. 1 in the first embodiment;

FIG. 3 is a cross-sectional view taken along line III-III shown in FIG. 1 in the first embodiment;

FIG. 4 is a cross-sectional view taken along line IV-IV shown in FIG. 1 in the first embodiment;

FIGS. 5A and 5B are cross-sectional views showing one manufacturing step of a manufacturing method of a nonvolatile semiconductor memory device in the second embodiment according to the present invention, where FIG. 5A is a cross-sectional view taken along the direction of a word line shown in FIG. 1 and FIG. 5B is a cross-sectional view taken along a direction intersecting over a region which becomes a channel and parallel to a bit line;

FIGS. 6A and 6B are cross-sectional views showing a step executed after the step shown in FIGS. 5A and 5B in the second embodiment, where FIG. 6A is a cross-sectional view taken along the direction of the word line shown in FIG. 1 and FIG. 6B is a cross-sectional view taken along the direction intersecting over the region which becomes the channel and parallel to the bit line;

FIGS. 7A and 7B are cross-sectional views showing a step executed after the step shown in FIGS. 6A and 6B in the second embodiment, where FIG. 7A is a cross-sectional view taken along the direction of the word line shown in FIG. 1 and FIG. 7B is a cross-sectional view taken along the direction intersecting over the region which becomes the channel and parallel to the bit line;

FIGS. 8A and 8B are cross-sectional views showing a step executed after the step shown in FIGS. 7A and 7B in the second embodiment, where FIG. 8A is a cross-sectional view taken along the direction of the word line shown in FIG. 1 and FIG. 8B is a cross-sectional view taken along the direction intersecting over the region which becomes the channel and parallel to the bit line;

FIGS. 9A and 9B are cross-sectional views showing a step executed after the step shown in FIGS. 8A and 8B in the second embodiment, where FIG. 9A is a cross-sectional view taken along the direction of the word line shown in FIG. 1 and FIG. 9B is a cross-sectional view taken along the direction intersecting over the region which becomes the channel and parallel to the bit line;

FIGS. 10A and 10B are cross-sectional views showing a step executed after the step shown in FIGS. 9A and 9B in the second embodiment, where FIG. 10A is a cross-sectional view taken along the direction of the word line shown in FIG. 1 and FIG. 10B is a cross-sectional view taken along the direction intersecting over the region which becomes the channel and parallel to the bit line;

FIGS. 11A and 11B are cross-sectional views showing a step executed after the step shown in FIGS. 10A and 10B in the second embodiment, where FIG. 11A is a cross-sectional view taken along the direction of the word line shown in FIG. 1 and FIG. 11B is a cross-sectional view taken along the direction intersecting over the region which becomes the channel and parallel to the bit line;

FIG. 12 is a plan view showing a step executed after the step shown in FIGS. 11A and 11B in the second embodiment;

FIGS. 13A, 13B and 13C are cross-sectional views showing the step shown in FIG. 12 in the second embodiment, where FIG. 13A is a cross-sectional view taken along a cross-sectional line XIIIA-XIIIA, FIG. 13B is a cross-sectional view taken along a cross-sectional line XIIIB-XIIIB and FIG. 13C is a cross-sectional view taken along a cross-sectional line XIIIC-XIIIC;

FIGS. 14A, 14B and 14C are cross-sectional views showing a step executed after the step shown in FIGS. 13A to 13C in the second embodiment, where FIG. 14A is a cross-sectional view corresponding to the cross-sectional line XIIIA-XIIIA shown in FIG. 12, FIG. 14B is a cross-sectional view corresponding to the cross-sectional line XIIIB-XIIIB shown in FIG. 12 and FIG. 14C is a cross-sectional view corresponding to the cross-sectional line XIIIC-XIIIC shown in FIG. 12;

FIGS. 15A, 15B and 15C are cross-sectional views showing a step executed after the step shown in FIGS. 14A to 14C in the second embodiment, where FIG. 15A is a cross-sectional view corresponding to the cross-sectional line XIIIA-XIIIA shown in FIG. 12, FIG. 15B is a cross-sectional view corresponding to the cross-sectional line XIIIB-XIIIB shown in FIG. 12 and FIG. 15C is a cross-sectional view corresponding to the cross-sectional line XIIIC-XIIIC shown in FIG. 12;

FIGS. 16A, 16B and 16C are cross-sectional views showing a step executed after the step shown in FIGS. 15A to 15C in the second embodiment, where FIG. 16A is a cross-sectional view corresponding to the cross-sectional line XIIIA-XIIIA shown in FIG. 12, FIG. 16B is a cross-sectional view corresponding to the cross-sectional line XIIIB-XIIIB shown in FIG. 12 and FIG. 16C is a cross-sectional view corresponding to the cross-sectional line XIIIC-XIIIC shown in FIG. 12;

FIGS. 17A, 17B and 17C are cross-sectional views showing a step executed after the step shown in FIGS. 16A to 16C in the second embodiment, where FIG. 17A is a cross-sectional view corresponding to the cross-sectional line XIIIA-XIIIA shown in FIG. 12, FIG. 17B is a cross-sectional view corresponding to the cross-sectional line XIIIB-XIIIB shown in FIG. 12 and FIG. 17C is a cross-sectional view corresponding to the cross-sectional line XIIIC-XIIIC shown in FIG. 12;

FIGS. 18A, 18B and 18C are cross-sectional views showing a step executed after the step shown in FIGS. 17A to 17C in the second embodiment, where FIG. 18A is a cross-sectional view corresponding to the cross-sectional line XIIIA-XIIIA shown in FIG. 12, FIG. 18B is a cross-sectional view corresponding to the cross-sectional line XIIIB-XIIIB shown in FIG. 12 and FIG. 18C is a cross-sectional view corresponding to the cross-sectional line XIIIC-XIIIC shown in FIG. 12;

FIGS. 19A, 19B and 19C are cross-sectional views showing a step executed after the step shown in FIGS. 18A to 18C in the second embodiment, where FIG. 19A is a cross-sectional view corresponding to the cross-sectional line XIIIA-XIIIA shown in FIG. 12, FIG. 19B is a cross-sectional view corresponding to the cross-sectional line XIIIB-XIIIB shown in FIG. 12 and FIG. 19C is a cross-sectional view corresponding to the cross-sectional line XIIIC-XIIIC shown in FIG. 12;

FIGS. 20A, 20B and 20C are cross-sectional views showing a step executed after the step shown in FIGS. 19A to 19C in the second embodiment, where FIG. 20A is a cross-sectional view corresponding to the cross-sectional line XIIIA-XIIIA shown in FIG. 12, FIG. 20B is a cross-sectional view corresponding to the cross-sectional line XIIIB-XIIIB shown in FIG. 12 and FIG. 20C is a cross-sectional view corresponding to the cross-sectional line XIIIC-XIIIC shown in FIG. 12;

FIG. 21 is a plan view of a flash memory as a nonvolatile semiconductor memory device in the third embodiment according to the present invention;

FIG. 22 is a cross-sectional view taken along a cross-sectional line XXII-XXII shown in FIG. 21 in the third embodiment;

FIG. 23 is a cross-sectional view taken along a cross-sectional line XXIII-XXIII shown in FIG. 21 in the third embodiment;

FIG. 24 is a cross-sectional view taken along a cross-sectional line XXIV-XXIV shown in FIG. 21 in the third embodiment;

FIGS. 25A and 25B are cross-sectional views showing a step of a manufacturing method of a semiconductor memory device in the fourth embodiment according to the present invention, where FIG. 25A is a cross-sectional view taken along the direction of a word line shown in FIG. 21 and FIG. 25B is a cross-sectional view taken along the direction of a bit line;

FIGS. 26A and 26B are cross-sectional views showing a step executed after the step shown in FIGS. 25A and 25B in the fourth embodiment, where FIG. 26A is a cross-sectional view taken along the word line direction shown in FIG. 21 and FIG. 26B is a cross-sectional view taken along the bit line direction;

FIGS. 27A and 27B are cross-sectional views showing a step executed after the step shown in FIGS. 26A and 26B in the fourth embodiment, where FIG. 27A is a cross-sectional view taken along the word line direction shown in FIG. 21 and FIG. 27B is a cross-sectional view taken along the bit line direction;

FIGS. 28A and 28B are cross-sectional views showing a step executed after the step shown in FIGS. 27A and 27B in the fourth embodiment, where FIG. 28A is a cross-sectional view taken along the word line direction shown in FIG. 21 and FIG. 28B is a cross-sectional view taken along the bit line direction;

FIG. 29 is a plan view showing a step executed after the step shown in FIGS. 28A and 28B in the fourth embodiment;

FIGS. 30A, 30B and 30C are cross-sectional views showing the step shown in FIG. 29 in the fourth embodiment, where FIG. 30A is a cross-sectional view taken along a cross-sectional line XXXA-XXXA shown in FIG. 29, FIG. 30B is a cross-sectional view taken along line XXXB-XXXB shown in FIG. 29 and FIG. 30C is a cross-sectional view taken along line XXXC-XXXC shown in FIG. 29;

FIGS. 31A, 31B and 31C are cross-sectional views showing a step executed after the step shown in FIGS. 30A to 30C in the fourth embodiment, where FIG. 31A is a cross-sectional view corresponding to the cross-sectional line XXXA-XXXA shown in FIG. 29, FIG. 31B is a cross-sectional view corresponding to XXXB-XXXB shown in FIG. 29 and FIG. 31C is a cross-sectional view corresponding to line XXXC-XXXC shown in FIG. 29;

FIGS. 32A, 32B and 32C are cross-sectional views showing a step executed after the step shown in FIGS. 31A to 31C in the fourth embodiment, where FIG. 32A is a cross-sectional view corresponding to the cross-sectional line XXXA-XXXA shown in FIG. 29, FIG. 32B is a cross-sectional view corresponding to XXXB-XXXB shown in FIG. 29 and FIG. 32C is a cross-sectional view corresponding to line XXXC-XXXC shown in FIG. 29;

FIGS. 33A, 33B and 33C are cross-sectional views showing a step executed after the step shown in FIGS. 32A to 32C in the fourth embodiment, where FIG. 33A is a cross-sectional view corresponding to the cross-sectional line XXXA-XXXA shown in FIG. 29, FIG. 33B is a cross-sectional view corresponding to XXXB-XXXB shown in FIG. 29 and FIG. 33C is a cross-sectional view corresponding to line XXXC-XXXC shown in FIG. 29;

FIGS. 34A, 34B and 34C are cross-sectional views showing a step executed after the step shown in FIGS. 33A to 33C in the fourth embodiment, where FIG. 34A is a cross-sectional view corresponding to the cross-sectional line XXXA-XXXA shown in FIG. 29, FIG. 34B is a cross-sectional view corresponding to XXXB-XXXB shown in FIG. 29 and FIG. 34C is a cross-sectional view corresponding to line XXXC-XXXC shown in FIG. 29;

FIGS. 35A, 35B and 35C are cross-sectional views showing a step executed after the step shown in FIGS. 34A to 34C in the fourth embodiment, where FIG. 35A is a cross-sectional view corresponding to the cross-sectional line XXXA-XXXA shown in FIG. 29, FIG. 35B is a cross-sectional view corresponding to XXXB-XXXB shown in FIG. 29 and FIG. 35C is a cross-sectional view corresponding to line XXXC-XXXC shown in FIG. 29;

FIGS. 36A, 36B and 36C are cross-sectional views showing a step executed after the step shown in FIGS. 35A to 35C in the fourth embodiment, where FIG. 36A is a cross-sectional view corresponding to the cross-sectional line XXXA-XXXA shown in FIG. 29, FIG. 36B is a cross-sectional view corresponding to XXXB-XXXB shown in FIG. 29 and FIG. 36C is a cross-sectional view corresponding to line XXXC-XXXC shown in FIG. 29;

FIG. 37 is a plan view of a conventional flash memory;

FIG. 38 is a cross-sectional view taken along a cross-sectional line XXXVIII-XXXVIII shown in FIG. 37;

FIG. 39 is a cross-sectional view taken along a cross-sectional line XXXIX-XXXIX shown in FIG. 37; and

FIG. 40 is a cross-sectional view taken along a cross-sectional line XL-XL shown in FIG. 37.

### DESCRIPTION OF THE PREFERRED EMBODIMENTS

### First Embodiment

An AND type flash memory will be described as one example of a nonvolatile semiconductor memory device in the first embodiment according to the present invention.

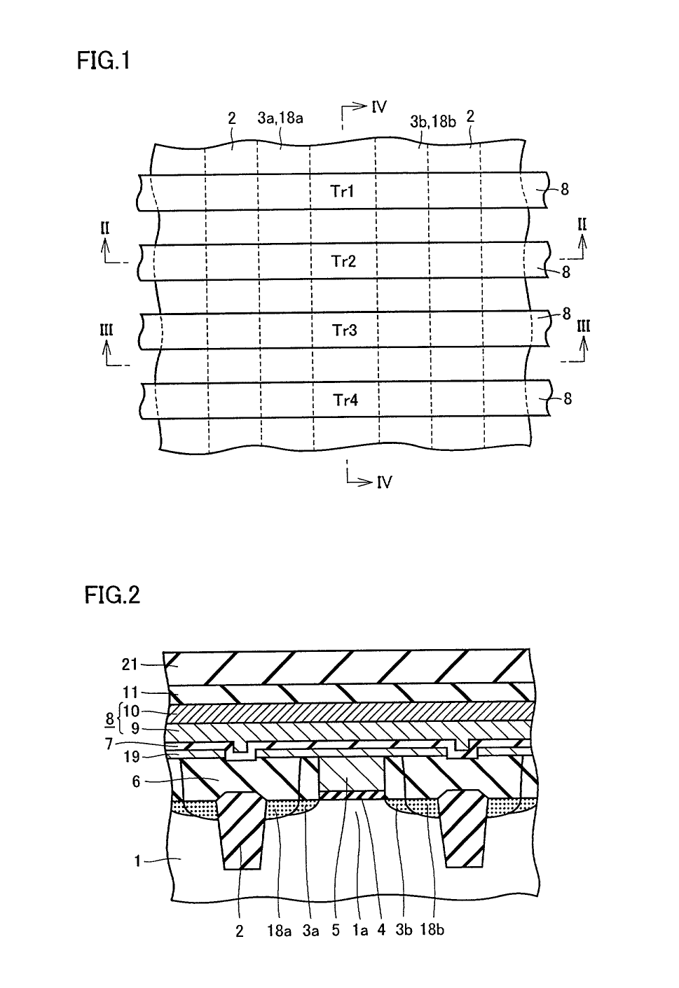

As shown in FIG. 1, source lines 3a, 18a and bit lines (drains) 3b, 18b are formed away from each other on the surface of the element formation region of a semiconductor substrate 1 formed by trench isolation regions 2. A floating gate electrode (see FIG. 2) is formed in the region of semiconductor substrate 1 put between source lines 3a, 18a and bit lines 3b, 18b.

Next, a cross-sectional structure along each cross-sectional line shown in FIG. 1 will be described. First, as shown in FIG. 2, on a cross section (cross-sectional line II-II) along word line 8, trench isolation oxide films 2 are formed on the surface of semiconductor substrate 1, and source lines 3a, 18a and bit lines 3b, 18b are formed in the element formation region put between trench isolation oxide films 2. A region 1a which becomes a channel is located in the region of semiconductor substrate 1 put between source lines 3a, 18a and bit lines 3b, 18b.

A thick insulating film 6 such as a silicon oxide film is formed on source lines 3a, 18a, bit lines 3b, 18b and trench isolation oxide films 2. A floating gate electrode 5 is formed on the surface of semiconductor substrate 1 put between source line 3a and bit line 3b with a tunnel oxide film 4 interposed.

A word line 8, consisting of a polysilicon film 9 and a tungsten silicide film 10, is formed on floating gate electrode 5 with an ONO film 7 interposed. It is noted that the ONO film is a film formed by building up a silicon oxide film and a silicon nitride film. An insulating film 11 such as a silicon oxide film is formed on word line 8. An interlayer insulating film 21 is formed on insulating film 11.

Memory cell transistors (Tr1, Tr2 and the like) shown in FIG. 1 are each constituted to include source lines 3a, 18a, bit lines 3b, 18b, floating gate electrode 5 and word line 8.

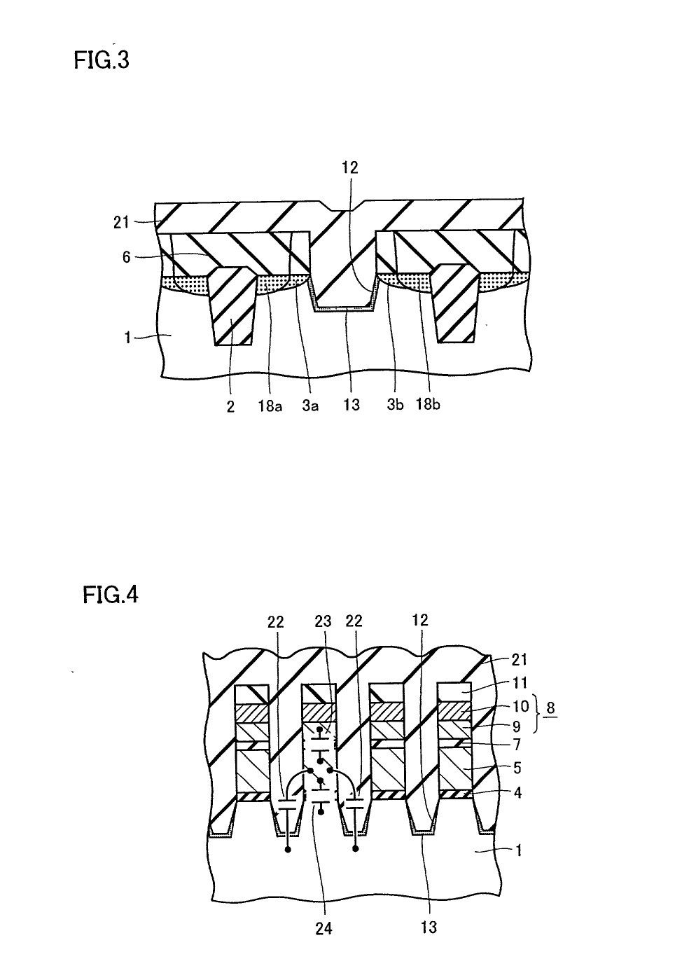

Next, as shown in FIG. 3, on a cross section (cross-sectional line III-III) along the region put between word lines 8, trench isolation oxide films 2 are formed on the surface of semiconductor substrate 1, and source lines 3a, 18a and bit lines 3b, 18b are formed in the element formation region put between trench isolation oxide film 2. Thick insulating film 6 is formed on source lines 3a, 18a, bit lines 3b, 18b and trench isolation oxide films 2. A recess 12 is formed, in particular, in the region of semiconductor substrate 1 located between source line 3a and bit line 3b.

Next, as shown in FIG. 4, on a cross section (cross-sectional line IV-IV) along the region put between source lines 3a, 18a and bit lines 3b, 18b, a plurality of floating gate electrodes 5 are formed away from one another on the surface of semiconductor substrate 1 with tunnel oxide films 4 interposed, respectively.

Word line 8, consisting of polysilicon film 9 and tungsten silicide 10, is formed on each floating gate electrode 5 with ONO film 7 interposed. An insulating film 11 such as a silicon oxide film is formed on the word line 8. Recesses 12 are formed in the regions of semiconductor substrate 1 put between floating gate electrodes 5, respectively.

Next, the operation of the flash memory stated above will be described. In case of, for example, reading information of transistor Tr2 shown in FIG. 1, the level of electrons stored in floating gate electrode 5 is determined depending on whether transistor Tr2 is turned on when a predetermined voltage is applied to bit lines 3b, 18b and a predetermined voltage is applied to word line 8 constituting transistor Tr2.

If transistor Tr2 is turned on, a current flows between source lines 3a, 18a and bit lines 3b, 18b through transistor Tr2. In the AND type flash memory, a plurality of transistors Tr1, Tr2 and the like are connected in parallel between, for example, source lines 3a, 18a and bit lines 3b, 18b.

As stated above, in the flash memory in this embodiment, recess 12 is formed in the region of semiconductor substrate 1 put between adjacent word lines 8 and put between source lines 3a, 18a and bit lines 3b, 18b. Namely, among the regions of semiconductor substrate 1 located around four side surfaces constituting floating gate electrode 5, the surface of the region part of semiconductor substrate 1 located on the side on which source lines 3a, 18a and bit lines 3b, 18b are not located is located below the surface of the channel region. By forming such recess 12, the distance between each side surface of floating gate electrode 5 and semiconductor substrate 1 is made longer.

As a result, among the capacitances between floating gate electrode 5 and semiconductor substrate 1, the capacitance Cs 22 between the side surface portion of floating gate electrode 5 and the region of semiconductor substrate 1 located below the side surface of floating gate electrode 5 becomes lower. Also, there is little difference, in the capacitance (tunnel region capacitance) 24 between the lower surface portion of floating gate electrode 5 and the region of semiconductor substrate 1 located right below the lower surface portion of floating gate electrode 5, between a case where recess 12 is formed and a case where recess 12 is not formed.

Due to this, it is possible to make the ratio of capacitance Cs 22 to tunnel region capacitance Cb 22 lower than that of the conventional flash memory. As a result, it is possible to improve the coupling capacitance ratio of the flash memory compared with that of the conventional flash memory and to thereby improve the performance of the flash memory.

Furthermore, in the flash memory stated above, as shown in FIG. 3, recess 12 is formed to be deeper than the portion on which source lines 3a, 18a and bit lines 3b, 18b serving as diffused layer wirings are located and an impurity region 13 opposite in conductive type to an impurity region forming source line 3a and bit line 3b on the surface of recess 12. Recess 12 is embedded with interlayer insulating film 21.

Accordingly, the structure of the flash memory becomes substantially equal to a structure in which relatively small trench isolation regions are formed in a region about half the size of the region of semiconductor substrate 1 put between source lines 3a, 18a and bit lines 3b, 18b.

As a result, compared with the conventional flash memory, it is possible to halve a leak current flowing between source lines 3a, 18a and bit lines 3b, 18b by forming such trench isolation regions.

### Second Embodiment

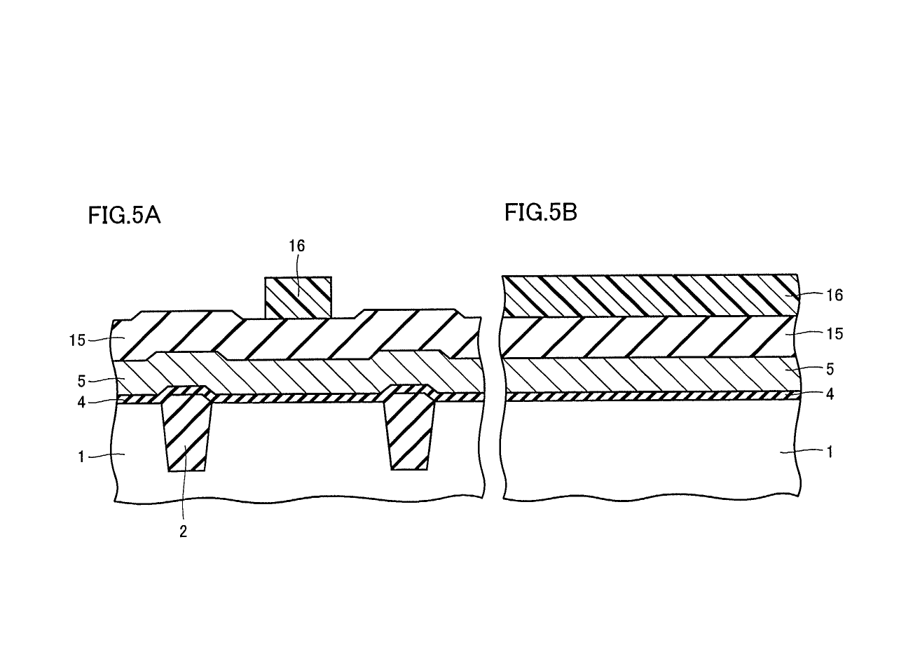

Next, description will be given, as the second embodiment, to one example of a method for manufacturing the AND type flash memory described in the first embodiment. First, description will be given to cross sections corresponding to the cross section (cross-sectional line II-II) along word line 8 shown in FIG. 1 and the cross section (cross-sectional line IV-IV) along bit line 3b shown in FIG. 1, respectively. As shown in FIGS. 5A and 5B, trench isolation oxide films 2 are formed in predetermined regions of semiconductor substrate 1, respectively. An element formation region is thereby formed.

On the surface of semiconductor substrate 1, tunnel oxide film 4 having a thickness of about 8.5 nm is formed by a thermal oxidation method. A phosphorus-doped amorphous silicon film 5 which becomes a part of floating gate electrode 5 is formed on tunnel oxide films 4. A silicon nitride film 15 is formed on phosphorus-doped amorphous silicon film 5. A photoresist 16 is formed on silicon nitride film 15.

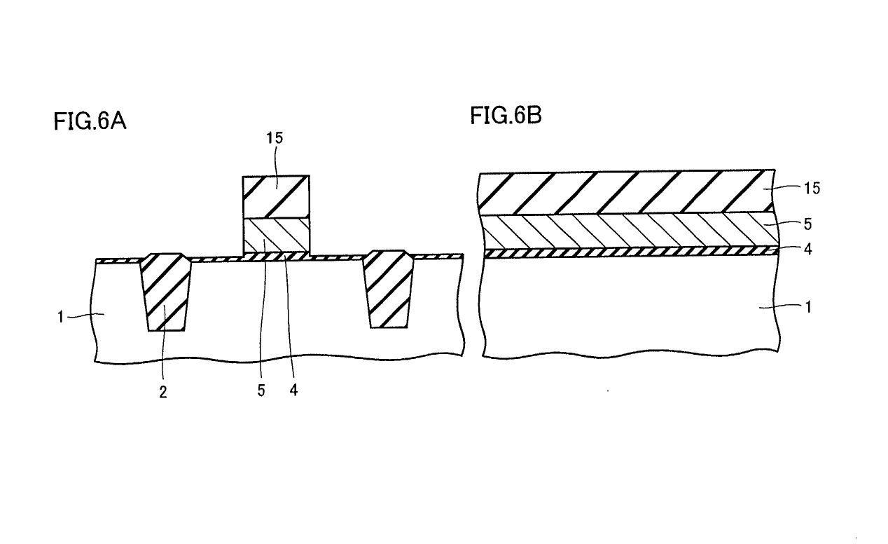

Next, as shown in FIGS. 6A and 6B, anisotropic etching is conducted to silicon nitride film 15 using photoresist 16 as a mask. Thereafter, photoresist 16 is removed, and anisotropic etching is conducted to amorphous-doped silicon film 5 using the patterned silicon nitride film as a mask, thereby exposing tunnel oxide film 4.

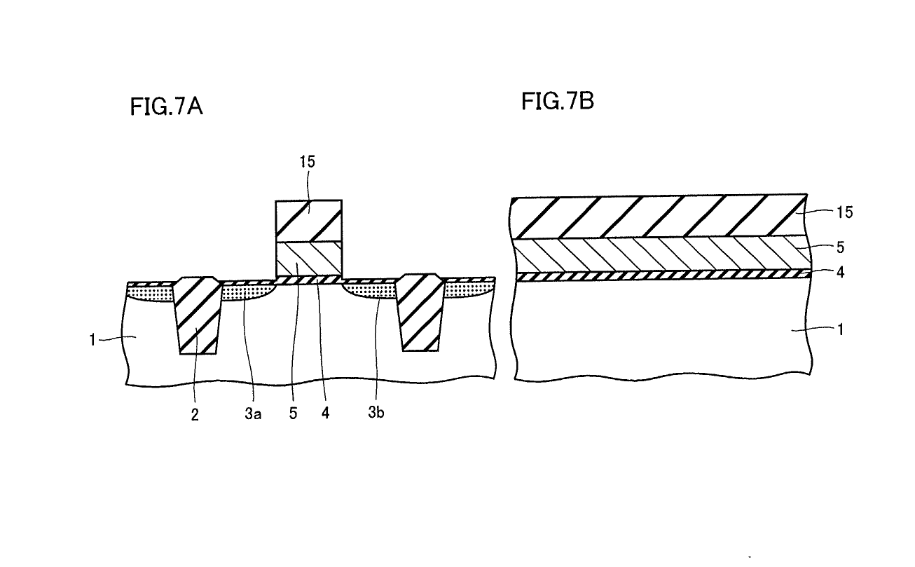

Next, as shown in FIGS. 7A and 7B, using amorphous-doped silicon film 5 which becomes a part of the floating gate electrode and silicon nitride film 15 as a mask, arsenic (As) ions, for example, are implanted into semiconductor substrate 1 with implantation energy of 30 KeV and a dose of 5×10¹³/cm², thereby forming source line 3a and bit line (drain) 3b serving as diffused layer wirings.

As a result, n-type source line 3a and n-type bit line 3b each having a depth of about 45 nm from the surface of semiconductor substrate 1 are formed in the region of semiconductor substrate 1 put between trench isolation oxide film 2 and amorphous-doped silicon film 5. The region of semiconductor substrate 1 located right below amorphous-doped silicon film 5 is a p type region.

It is noted that the depth of each of source line 3a and bit line 3b means a depth defined by R_{ρ}+3×ΔR_{ρ}where mean projection degree of ion species is R_{ρ} and dispersion thereof is ΔR_{ρ}.

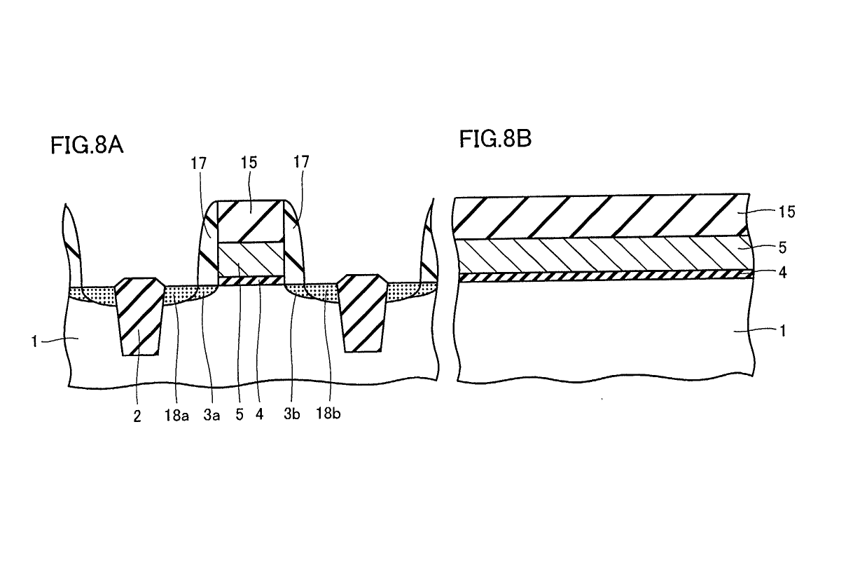

Then, a silicon oxide film (not shown) is formed to cover amorphous-doped silicon film 5 which becomes a part of the floating gate electrode and silicon nitride film 15. The silicon oxide film is subjected to anisotropic etching, thereby forming sidewall insulating films 17 on the both sides of amorphous-doped silicon film 5, respectively, as shown in FIGS. 8A and 8B.

Using sidewall insulating films 17 and the like as a mask, arsenic (As) ions are further implanted into semiconductor substrate 1 with implantation energy of 30 KeV and a dose of 1×10¹⁵/cm², thereby forming source line 18a and bit line (drain) 18b serving as diffused layer wirings. The reason for further implanting arsenic ions is to decrease the resistance of the diffused layer wirings. In addition, the depth by which arsenic ions are implanted is almost the same as that by which arsenic ions previously described are implanted.

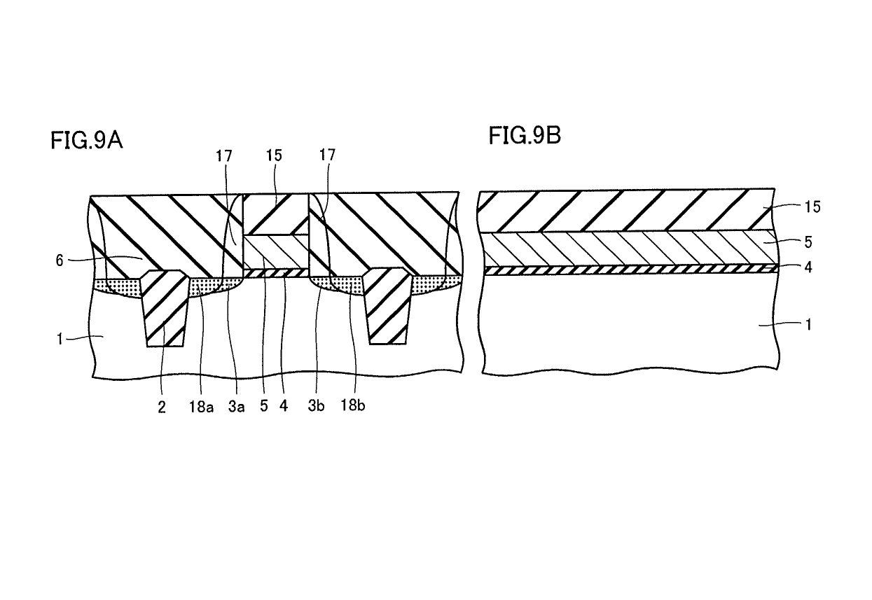

Thereafter, a silicon oxide film (not shown) having a thickness of about 450 nm is formed on semiconductor substrate by, for example, a CVD (Chemical Vapor Deposition) method. Then, as shown in FIGS. 9A and 9B, the silicon oxide film is subjected to chemical mechanical polishing (CMP), thereby exposing the surface of silicon nitride film 15. As a result, thick insulating film 6 having a relatively large thickness is formed on source lines 3a, 18a and bit lines 3b, 18b serving as the diffused layer wirings and thick insulating film 6 surrounds amorphous-doped silicon film 5 which becomes a part of the floating gate electrode.

Thereafter, dry etching is conducted to etch thick insulating film 6 by about 180 nm. Silicon nitride film 15 is also etched simultaneously with the etching of thick insulating film 6. Further, silicon nitride film 15 remaining on amorphous-doped silicon film 5 is removed almost completely by a thermal phosphoric acid and the surface of amorphous-doped silicon film 5 is washed by a hydrofluoric acid (HF).

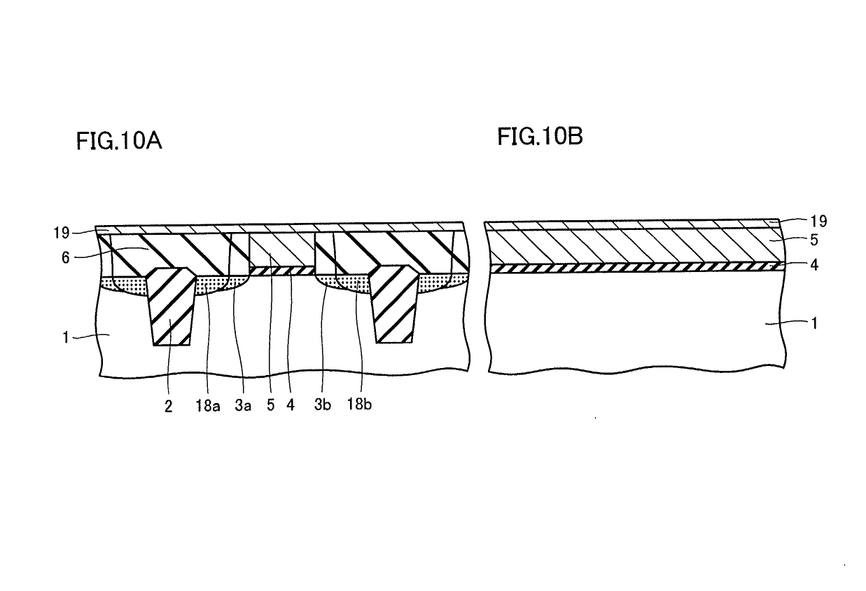

As shown in FIGS. 10A and 10B, a phosphorus-doped amorphous silicon film 19 is formed on the surface of amorphous-doped silicon film 5 thus washed. This phosphorus-doped amorphous silicon film 19 also becomes a part of the floating gate electrode. A predetermined photoresist (not shown) is formed on phosphorus-doped amorphous silicon film 19. This photoresist is desirably patterned to have openings in regions above trench isolation oxide films 2.

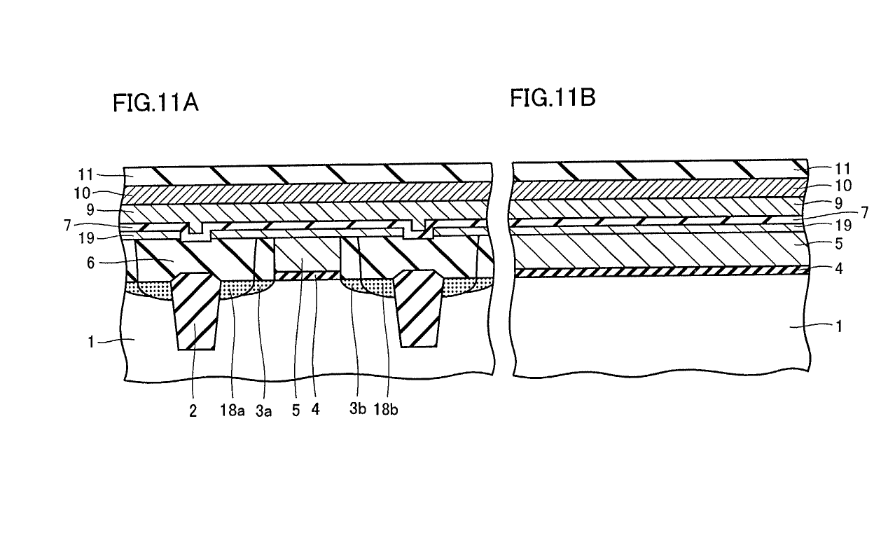

Using the photoresist as a mask, phosphorus-doped amorphous silicon film 19 is etched. As a result, as shown in FIG. 11A, phosphorus-doped amorphous silicon film 19 which becomes a part of the floating gate electrode is formed. Also, as shown in Fig. 11B, on a cross section along a cross-sectional line intersecting over the region which becomes a channel in parallel to the bit lines, phosphorus-doped amorphous silicon film 19 and amorphous-doped silicon film 5 constituting the floating gate are continuous to each other.

Thereafter, as shown in FIGS. 11A and 11B, ONO film 7 is formed by building up a silicon oxide film and a silicon nitride film on phosphorus-doped amorphous silicon film 19. Next, after the entire memory cell region is covered with a photoresist (not shown), the ONO film, the phosphorus-doped amorphous silicon films and the tunnel oxide film existing in a peripheral circuit region (not shown) are sequentially subjected to dry etching or wet etching, thereby removing the ONO film, the phosphorus-doped amorphous silicon films and the tunnel oxide film. The photoresist is then removed and the gate oxide film of a transistor in the peripheral circuit region is formed by the thermal oxidation method.

Thereafter, as shown in FIGS. 11A and 11B, polysilicon film 9 having a thickness of about 100 nm is formed by, for example, the CVD method. Tungsten silicide film 10 having a thickness of about 100 nm is formed on polysilicon film 9. Silicon oxide film 11 having a thickness of about 250 nm is formed on tungsten silicide film 10 by the CVD method.

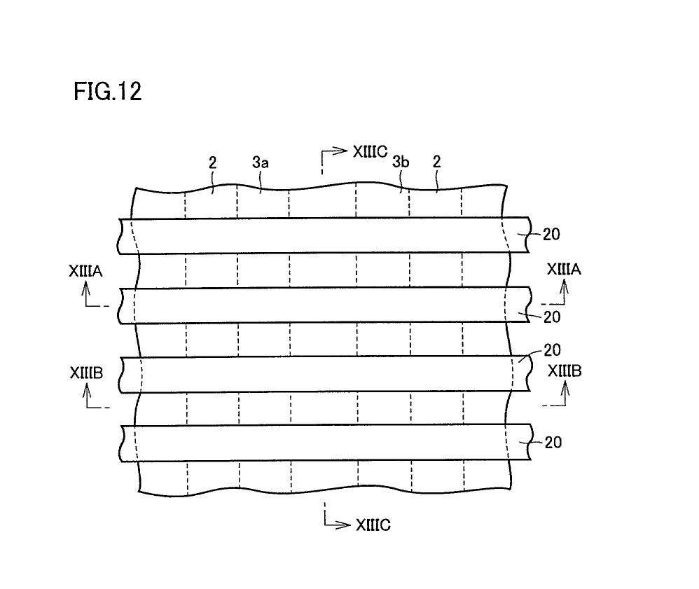

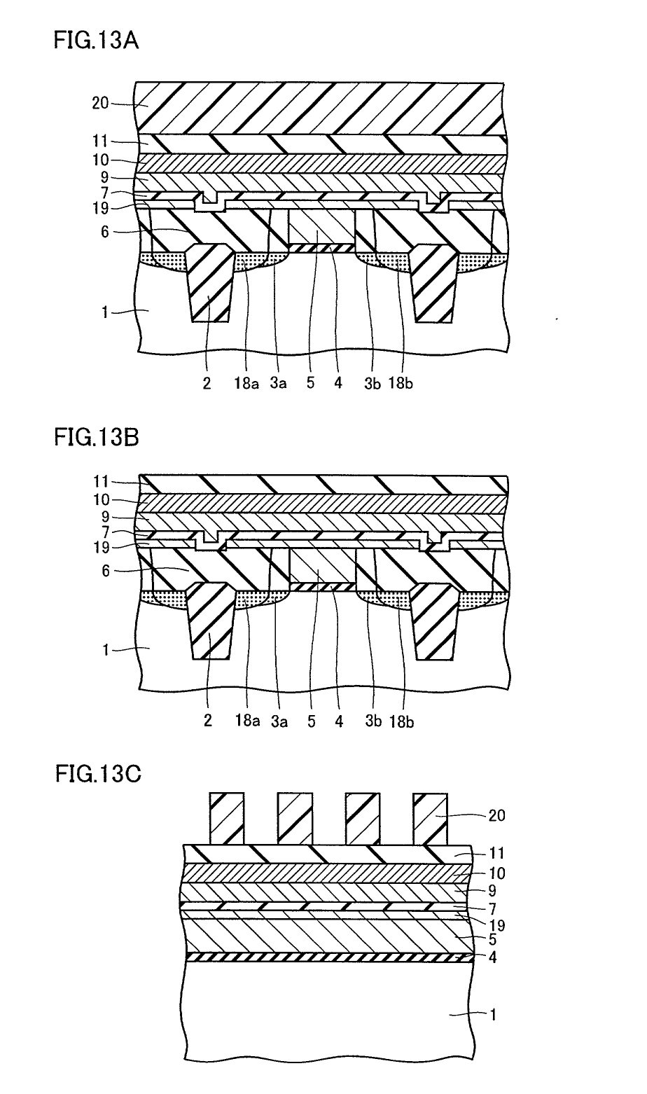

Next, as shown in FIG. 12, photoresists 20 are formed on the semiconductor substrate to pattern word lines. At this moment, as shown in FIG. 13A, on a cross section along a region in which a word line is formed, photoresist 20 is formed. Also, as shown in FIG. 13B, on a cross section along a region in which no word line is formed, photoresist 20 is not formed. Further, as shown in FIG. 13C, on a cross section along a direction almost orthogonal to a direction in which a word line is formed, a plurality of photoresists 20 are formed.

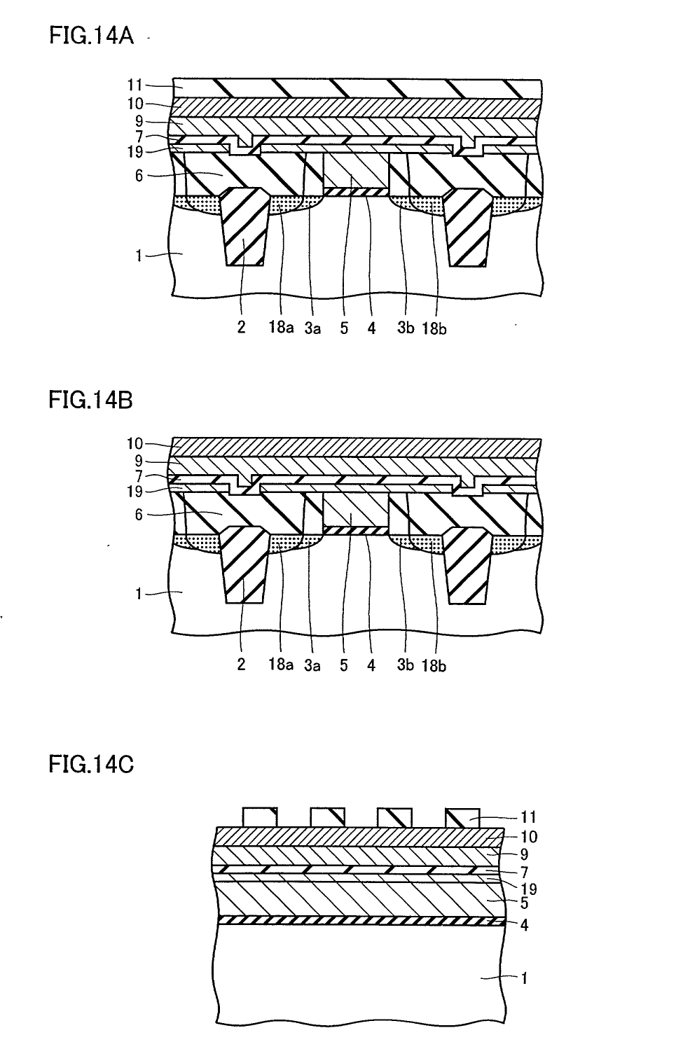

Next, as shown in FIGS. 14A to 14C, using photoresist 20 as a mask, silicon oxide film 11 is subjected to anisotropic etching to thereby form silicon oxide film 11 serving as a mask material for patterning a word line.

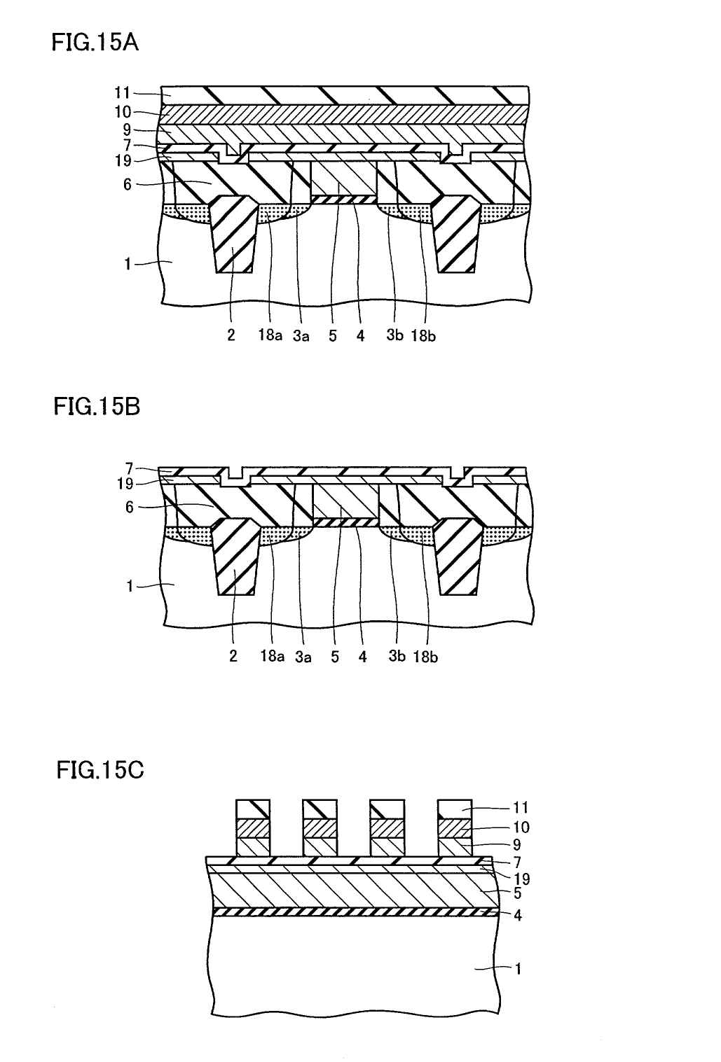

Next as shown in FIGS. 15A to 15C, using silicon oxide film 11 as a mask, tungsten silicide film 10 and polysilicon film 9 are subjected to dry etching, thereby exposing the surface of ONO film 7. At this moment, in the peripheral circuit region, although not shown in the drawings, the gate electrode of a transistor is formed. Then, a photoresist (not shown) covering the peripheral circuit region and having openings in the memory cell region is formed.

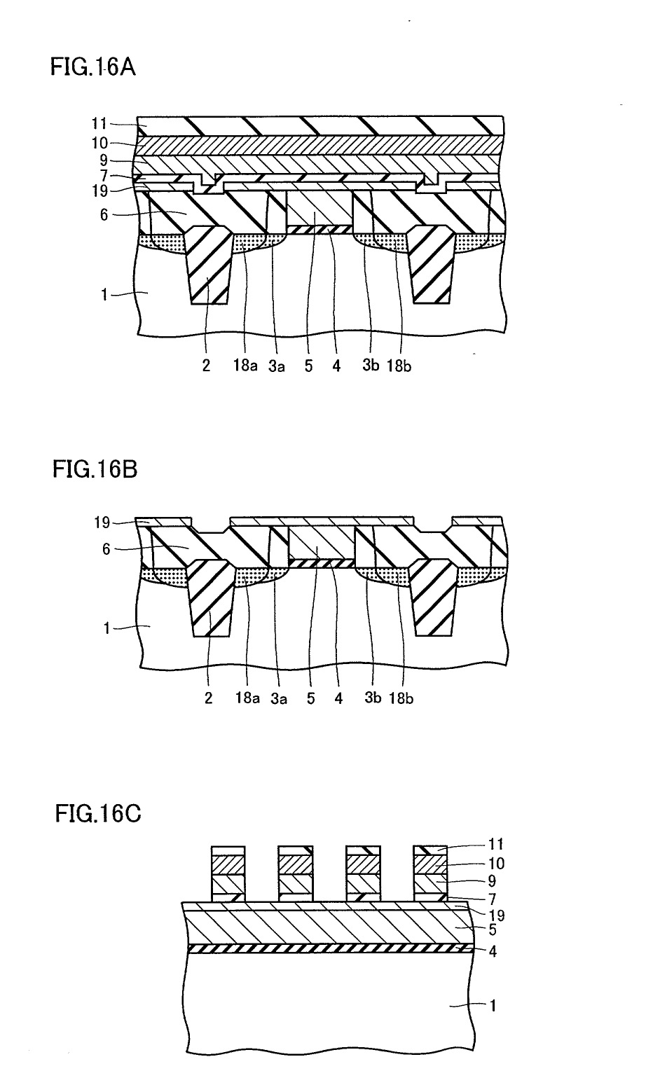

Next, as shown in FIGS. 16A to 16C, using the photoresist as a mask, exposed ONO film 7 is subjected to anisotropic etching, thereby removing ONO film 7 and exposing phosphorus-doped amorphous silicon film 19.

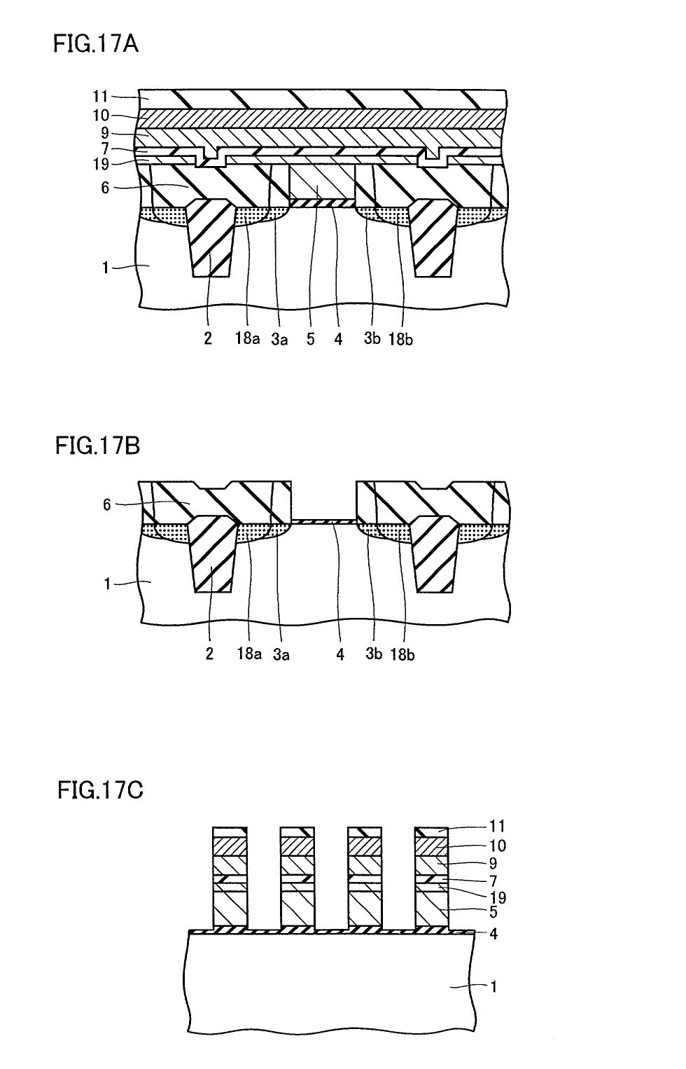

Next, as shown in FIGS. 17A to 17C, dry etching is conducted to thereby remove phosphorus-doped amorphous silicon films 19 and 5 and to expose tunnel oxide film 4. Namely, etching is temporarily stopped on tunnel oxide film 4. Thereafter, by conducting wet etching or dry etching using a hydrofluoric acid (HF), exposed tunnel oxide film 4 is removed and the surface of semiconductor substrate 1 is exposed. As a result, word lines 8 and floating gate electrodes 5 are formed.

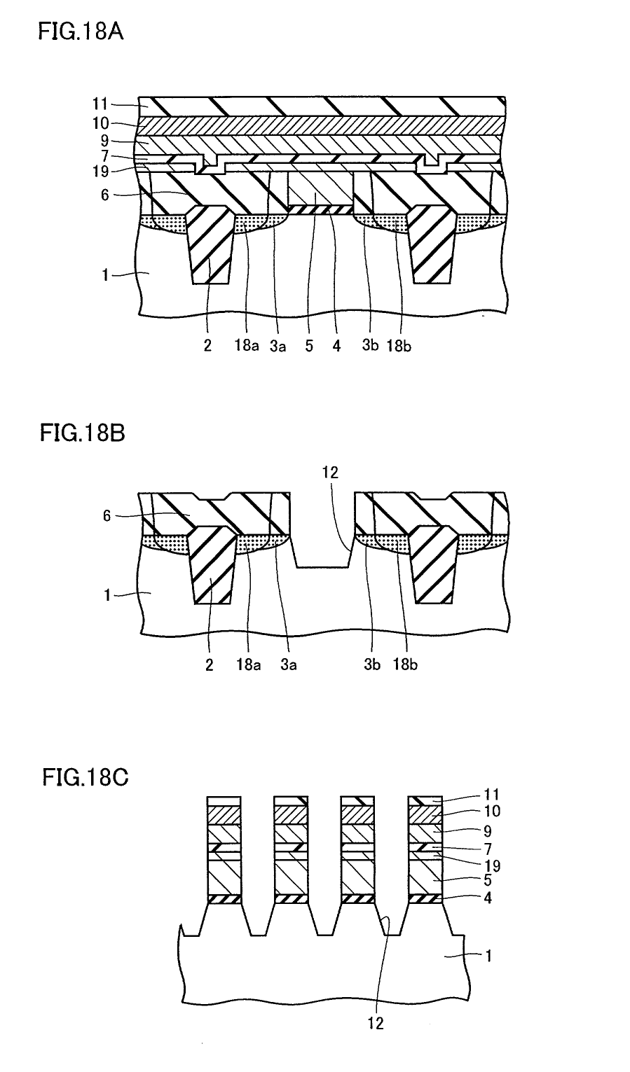

Next, as shown in FIGS. 18A to 18C, the surface of exposed semiconductor substrate 1 is subjected to dry etching, thereby forming recess 12. At this moment, if etching is conducted by, for example, ECR (Electron Cyclotron Resonance) discharge, it is preferable that gas containing chlorine and oxygen is employed as etching gas, pressure is about 0.4 Pa, RF power is about 50 W and microwave power is about 400 W.

Further, it is preferable that the depth of recess 12 is larger than those of source lines 3a, 18a and bit lines 3b, 18b, e.g., about 80 nm.

This manufacturing process will be described in more detail. In FIG. 12 to FIGS. 18A to 18C stated above, it is the region put between the word lines and put between thick insulating films that is subjected to etching. In this region, the phosphorus-doped amorphous silicon films which become the floating gate electrode exist. As already described above, source lines 3a, 18a and bit lines 3b, 18b serving as diffused layer wirings are formed by implanting ions using the phosphorus-doped amorphous silicon films as a mask. Thick insulating films 6 are provided on the diffused layer wirings.

Accordingly, by forming recesses 12 in semiconductor substrate 1 through a series of etching operations stated above, the p type region of the semiconductor substrate located between source lines 3a, 18a and bit lines 3b, 18b and causing a leak current is removed in a self-aligned manner.

At this moment, the region (p type region) of semiconductor substrate 1, i.e., the channel region located below the word lines and put between source lines 3a, 18a and bit lines 3b, 18b, and source lines 3a, 18a and bit lines 3b, 18b (n type region) are not influenced by etching.

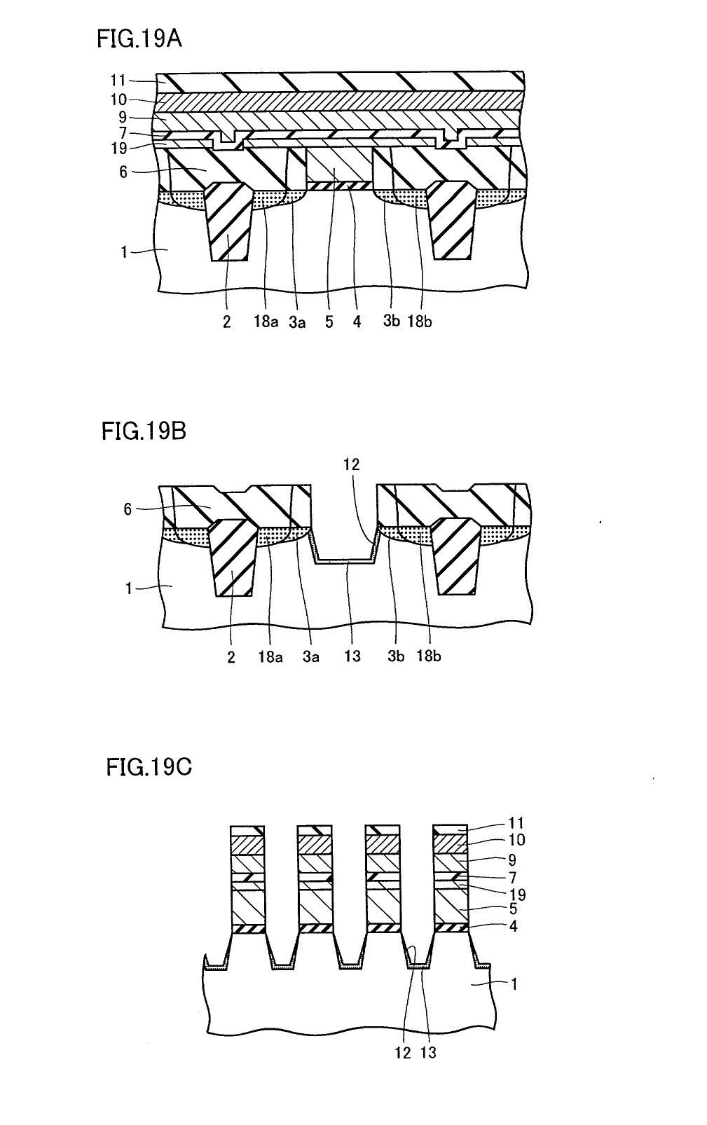

Next, as shown in FIGS. 19A to 19C, boron (B) ions are implanted into the surface of each recess 12 with implantation energy of 20 KeV and a dose of 1×10¹³/cm², thereby removing impurity region 13. Thereafter, the photoresist formed in the peripheral circuit region is removed.

Although this implantation step is not necessarily indispensable, it is possible to advantageously decrease a leak current between source lines 3a, 18a and bit lines 3b, 18b by forming the impurity region opposite in conductive type to the diffused layer wirings. Also, in this step, each recess 12 is formed deeper than source lines 3a, 18a and bit lines 3b, 18b, thereby preventing junction withstand voltage from lowering even if boron ions are implanted.

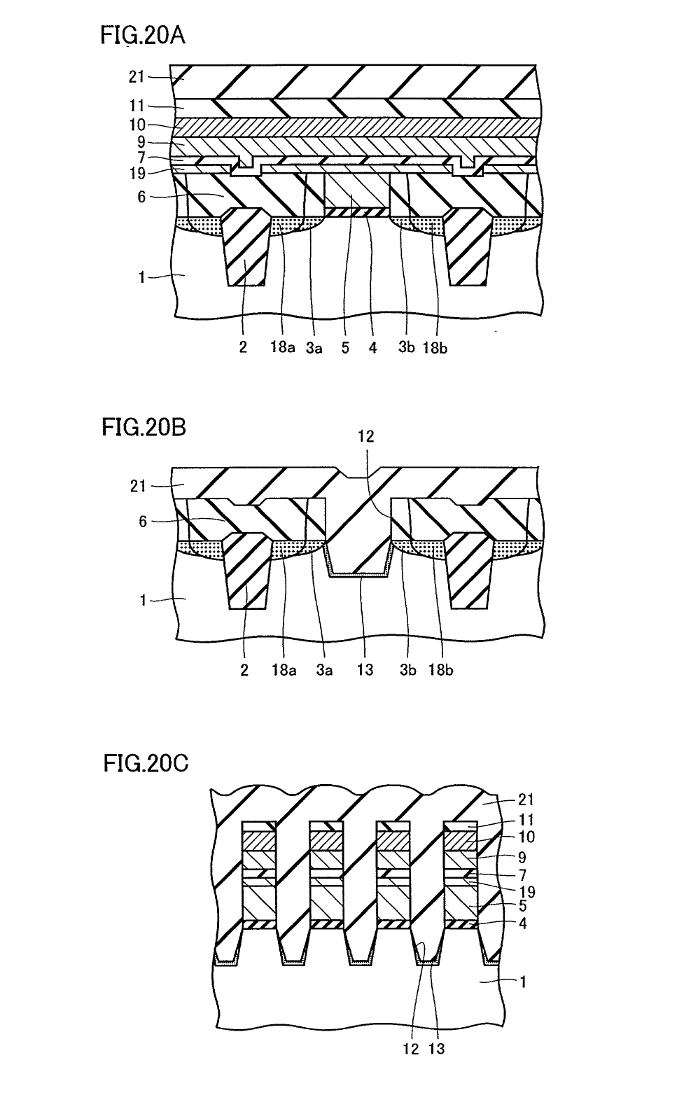

Thereafter, in the peripheral circuit region (not shown), the sources and drains of p type and n type transistors are formed. As shown in FIGS. 20A to 20C, interlayer insulating film 21 such as a silicon oxide film is formed on semiconductor substrate 1 to cover word lines 8 and the like for example, by the CVD method. As a result, the main parts of the flash memory shown in FIGS. 1 to 4 are completed.

In this flash memory, capacitance Cs 22 between the side surface portion of floating gate electrode 5 and the region of semiconductor substrate located below the side surface portion of floating gate electrode 5 is made lower by forming recess 12 and embedding recess 12 with interlayer insulating film 21 as already stated above. As a result, it is possible to improve the coupling capacitance ratio of the flash memory compared with that of the conventional flash memory and to thereby improve the performance of the flash memory.

In the above-stated manufacturing method of a flash memory, it is possible to easily form each recess 12 in a self-aligned manner by etching the region of semiconductor substrate 1 put between word lines 8 and thick insulating films 6 using silicon oxide films 11 and thick insulating films 6 on word lines 8 as a mask.

Further, by embedding each recess 12 with interlayer insulating film 21, the same advantage as that obtained by forming trench isolation regions can be obtained, making it possible to halve a leak current between source line 3a and bit line 3b.

Furthermore, by forming impurity region 13 opposite in conductive type to semiconductor substrate 1 on the surface of each recess 12, it is possible to further advantageously decrease a leak current between source lines 3a, 18a and bit lines 3b, 18b.

In the above-stated manufacturing method of a flash memory, etching is temporarily stopped when tunnel oxide film 4 is exposed in the step shown in FIGS. 17A to 17C. However, it is also possible to etch semiconductor substrate 1 exposed following the etching to form recesses 12.

### Third Embodiment

In the first embodiment, description has been given while taking the AND type flash memory as an example of the flash memory. In the third embodiment described hereinafter, an NAND type flash memory will be described as another example of the flash memory.

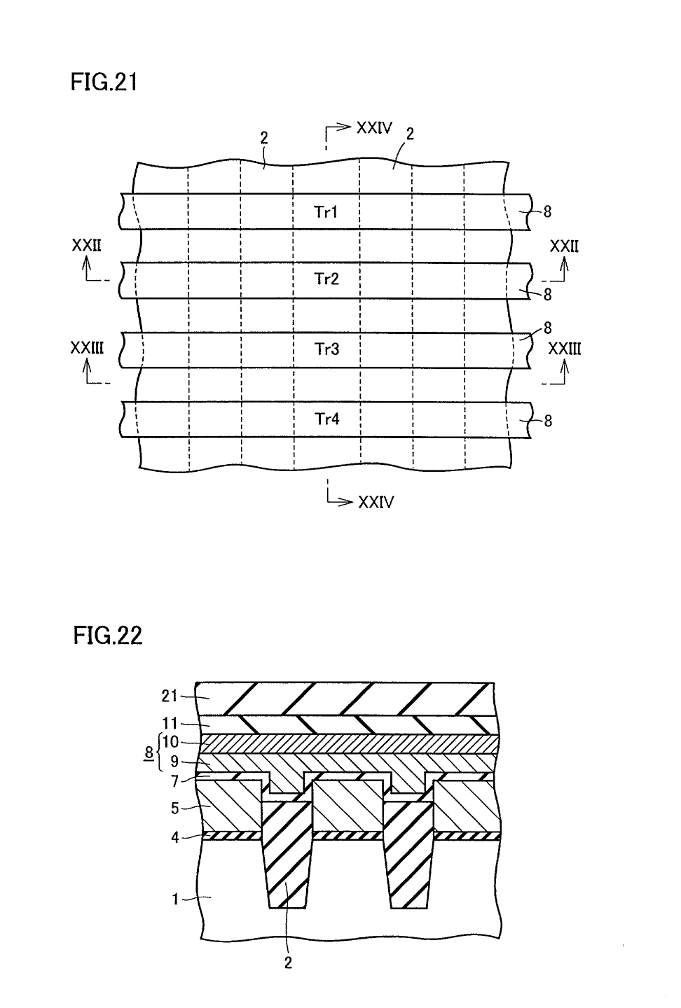

As shown in FIG. 21, an element formation region is provided by tunnel isolation oxide films 2 formed away from each other on the surface of semiconductor substrate 1. A plurality of word lines 8 are formed in a direction almost orthogonal to trench isolation oxide films 2. In the element formation region, a plurality of transistors Tr1, Tr2 and the like are formed.

Next, a cross-sectional structure along each cross-sectional line shown in FIG. 21 will be described. First, as shown in FIG. 22, on a cross section (cross-sectional line XXII-XXII) along word line 8, trench isolation oxide films 2 are formed on the surface of semiconductor substrate 1 and floating gate electrode 5 is formed in the region (element formation region) of semiconductor substrate 1 put between trench isolation oxide films 2 with tunnel oxide film 4 interposed.

On floating gate electrode 5, word line 8 consisting of polysilicon film 9 and tungsten silicide film 10 is formed with ONO film 7 interposed. Insulating film 11 such as a silicon oxide film is formed on word line 8. Interlayer insulating film 21 is further formed on insulating film 11.

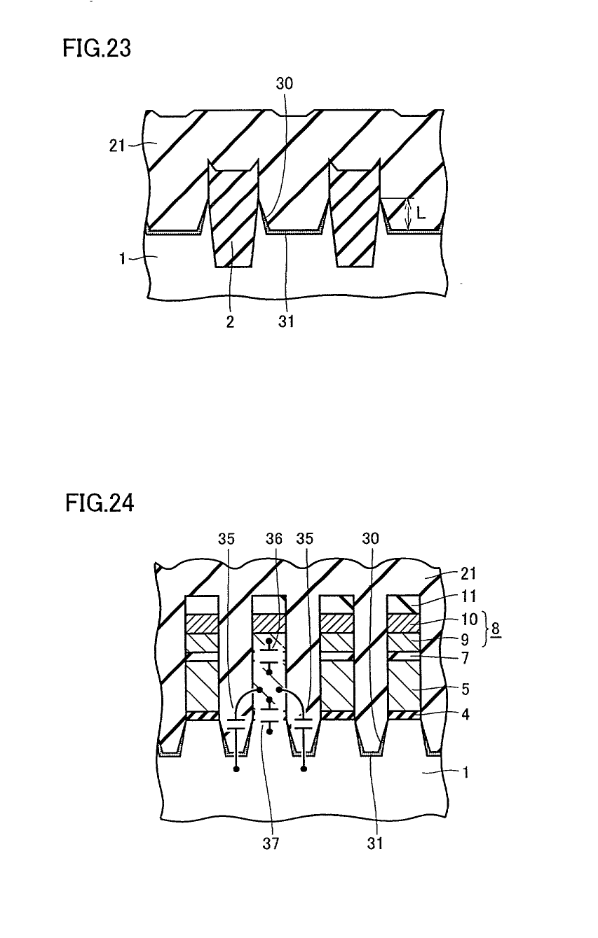

Next, as shown in FIG. 23, on a cross section (cross-sectional line XXIII-XXIII) along the region put between word lines 8, trench isolation oxide films 2 are formed on the surface of semiconductor substrate 1 and recesses 30 are formed in the regions (element formation regions) of semiconductor substrate 1 put between trench isolation oxide films 2, respectively. The depth L of each recess 30 is not less than about 50 nm. An impurity region 31 forming a source region or a drain region is formed on the surface of each recess 30. Interlayer insulating film 21 is formed to embed recesses 30.

Next, as shown in FIG. 24, on a cross section (cross-sectional line XXIV-XXIV) along the region put between trench isolation oxide films 2, each recesses 30 stated above is located in each region of semiconductor substrate 1 put between word lines 8. A plurality of floating gate electrodes 5 are formed away from one another on the surface of semiconductor substrate 1 with tunnel oxide films 4 interposed, respectively. A word line 8 consisting of polysilicon film 9 and tungsten silicide film 10 is formed on each floating gate 5 with ONO film 7 interposed. Insulating film 11 such as a silicon oxide film is formed on each word line 8. Interlayer insulating film 21 is formed to embed each recess 30.

In the above-stated NAND type flash memory, respective transistors Tr1, Tr2 and the like shown in FIG. 21 are connected in series through impurity regions 31 each serving as the source region or the drain region.

Accordingly, if a predetermined threshold voltage is applied to a specific transistor among plural transistors Tr1, Tr2 and the like connected in series, a voltage equal to or higher than the threshold voltage is applied to the remaining transistors and the specific transistor is turned on, then a current flows between the both ends of the serially connected transistors. On the other hand, if the specific transistor is turned off, no current flows between the both ends thereof. In this way, the level of electrons stored in the specific transistor is determined.

In the above-stated flash memory, recess 30 is formed in each region of semiconductor substrate 1 put between adjacent word lines 8 and trench isolation oxide films 2. That is, each recess 30 is formed in the regions of semiconductor substrate 1 located on the side on which trench isolation oxide films 2 are not located among the regions of semiconductor substrate 1 located around the fourth side surfaces constituting each floating gate electrode 5.

As shown in FIG. 24, by forming recesses 30, the distance between the side surface of each word line 8 and semiconductor substrate 1 is made longer. As a result, the capacitance Cs 35 between the side surface portion of floating gate electrode 5 and the region of semiconductor substrate 1 located below the side surface portion of floating gate electrode 5 becomes lower among the capacitances between floating gate electrode 5 and semiconductor substrate 1.

Further, there is little difference in the capacitance (tunnel region capacitance) 37 between the lower surface portion of floating gate electrode 5 and the region of semiconductor substrate 1 located right below the lower surface portion of floating gate electrode 5 between a case where recess 30 is formed and a case where recess 30 is not formed.

It is, therefore, possible to decrease the ratio of capacitance Cs 35 to tunnel region capacitance Cb 37 compared with that of the conventional flash memory. As a result, it is possible to improve the coupling capacitance ratio of the flash memory compared with that of the conventional flash memory and to thereby improve the performance of the flash memory.

### Fourth Embodiment

Next, description will be given, as the fourth embodiment, one example of a method for manufacturing the above-stated NAND type flash memory. In this manufacturing method, steps after forming the word lines to which importance is attached are substantially the same as those in the above-stated manufacturing method. Also, since diffused layer wirings are not formed, steps until the word lines are formed are slightly different from those of the above-stated method.

Further, in the fourth embodiment, description will be given to a case of forming element isolation oxide films simultaneously with floating gate electrodes by a so-called self align trench isolation method or STI method. The STI method is a well-known technique.

Now, description will be given to cross sections corresponding to the cross section (cross-sectional line XXII-XXII) along word line 8 and the cross section along the direction almost orthogonal to word lines 8 (bit line direction), respectively in FIG. 21.

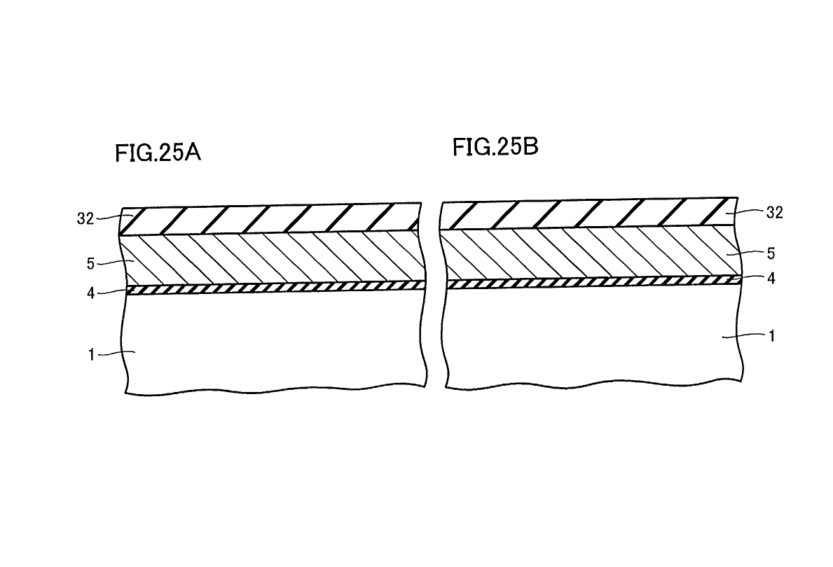

First, as shown in FIGS. 25A and 25B, tunnel oxide film 4 having a thickness of about 8.5 nm is formed on the surface of semiconductor substrate 1 by the thermal oxidation method. Phosphorus-doped amorphous silicon film 5 which becomes a part of a floating gate electrode is formed on tunnel oxide film 4. Silicon nitride film 32 is formed on phosphorus-doped amorphous silicon film 5. A photoresist (not shown) is formed on silicon nitride film 32. Using this photoresist as a mask, silicon nitride film is subjected to anisotropic etching, thereby forming silicon nitride film 32 as a mask material.

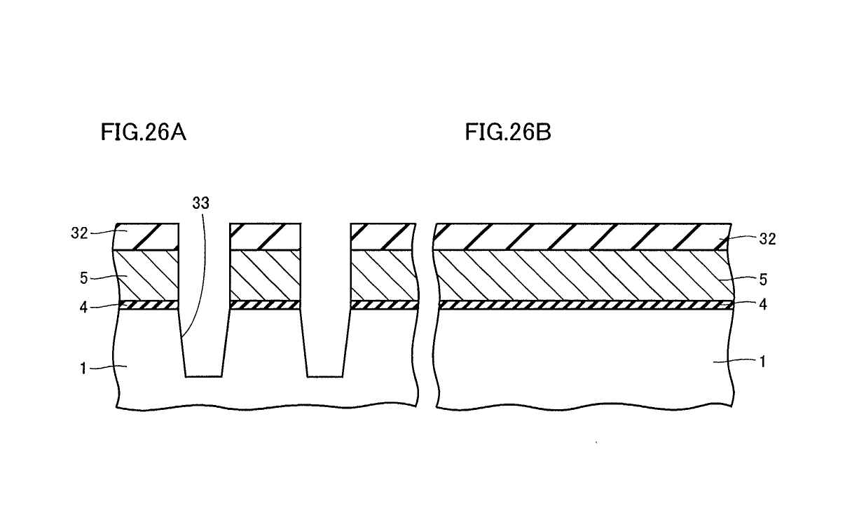

Next, as shown in FIGS. 26A and 26B, using patterned silicon nitride film 32 as a mask, amorphous-doped silicon film 5, tunnel oxide film 4 and semiconductor substrate 1 are sequentially subjected to anisotropic etching (trench etching) to thereby form opening portions 33. Thus, opening portions 33 for self-align trench isolation are formed. Thereafter, the inner walls of opening portions 33 are oxidized by about 15 nm (not shown) under a dry atmosphere at a temperature of about 850° so as to repair damages inflicted by the trench etching.

Thereafter, a silicon oxide film (not shown) having a thickness of about 600 nm is formed on the semiconductor substrate by, for example, the CVD method. Then, the silicon oxide film is subjected to chemical mechanical polishing (CMP). Next, dry etching is conducted to etch the silicon oxide film by about 15 nm.

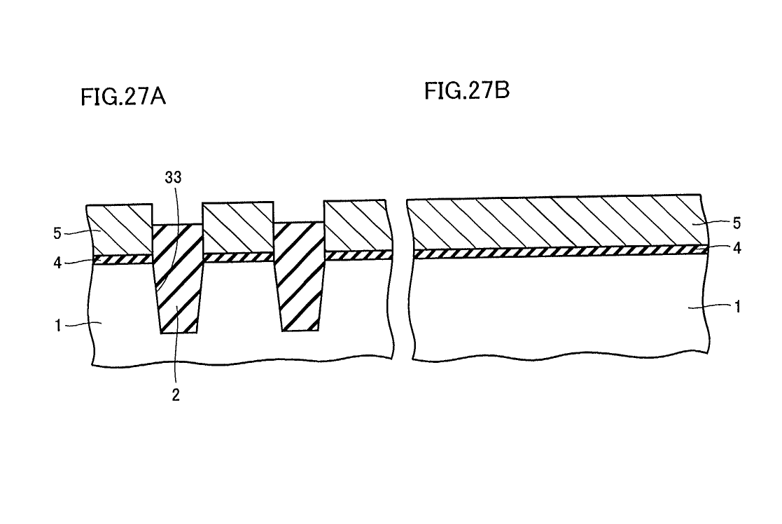

Next, as shown in FIGS. 27A and 27B, silicon nitride film 32 is removed by a thermal phosphoric acid. A trench isolation oxide films 2 are formed whereby.

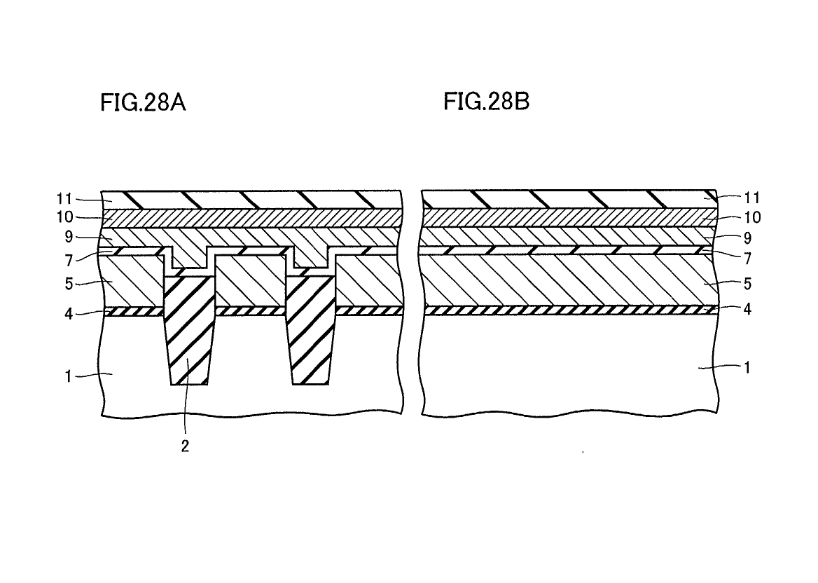

Next, as shown in FIGS. 28A and 28B, a silicon oxide film and a silicon nitride film are built up on amorphous-doped silicon film 5 which becomes the floating gate electrode, thereby forming ONO film 7. Next, polysilicon film 9 having a thickness of about 80 nm is formed by, for example, the CVD method. Tungsten silicide film 10 having a thickness of about 100 nm is formed on polysilicon film 9. Silicon oxide film 11 having a thickness of about 100 nm is formed on tungsten silicide film 10 by the CVD method.

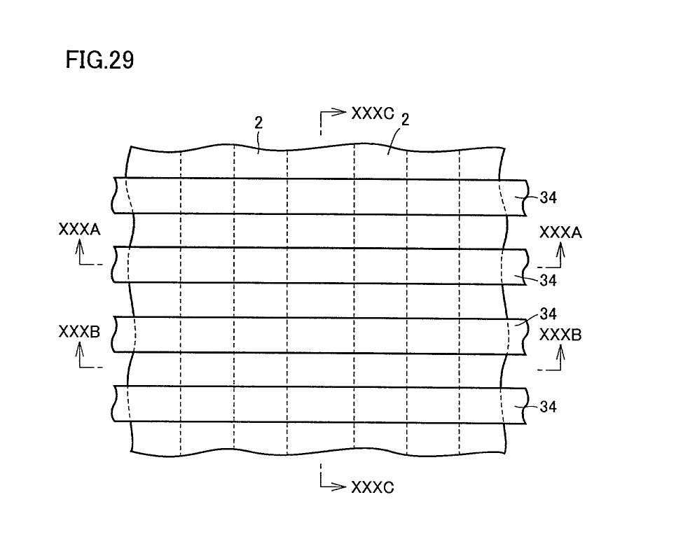

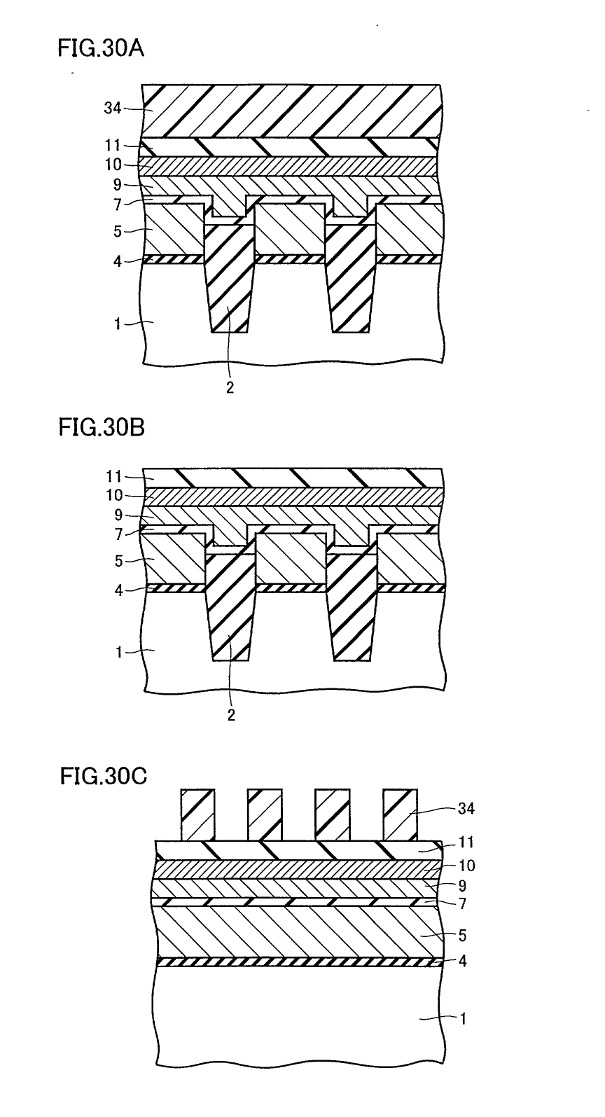

Next, as shown in FIG. 29, photoresists 34 are formed to pattern word lines. At this moment, as shown in FIG. 30A, on a cross section (cross-sectional line XXXA-XXXA) along a region in which a word line is formed, photoresist 34 is formed. As shown in FIG. 30B, on a cross section (cross-sectional line XXXB-XXXB) along a region in which no word line is formed, photoresist 34 is not formed. Further, as shown in FIG. 30C, on a cross section (cross-sectional line XXXC-XXXC) along a direction almost orthogonal to a direction in which word lines are formed, a plurality of photoresists 34 are formed.

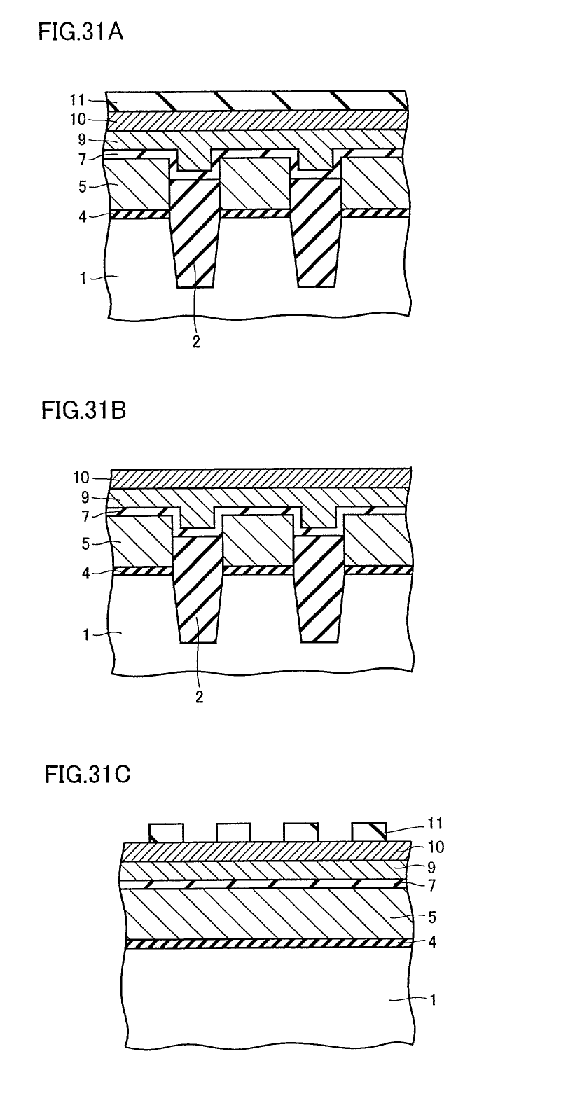

Next, as shown in FIGS. 31A to 31C, using photoresist 34 as a mask, silicon oxide film 11 is subjected to anisotropic etching, thereby forming silicon oxide film 11 serving as a mask material for patterning word lines.

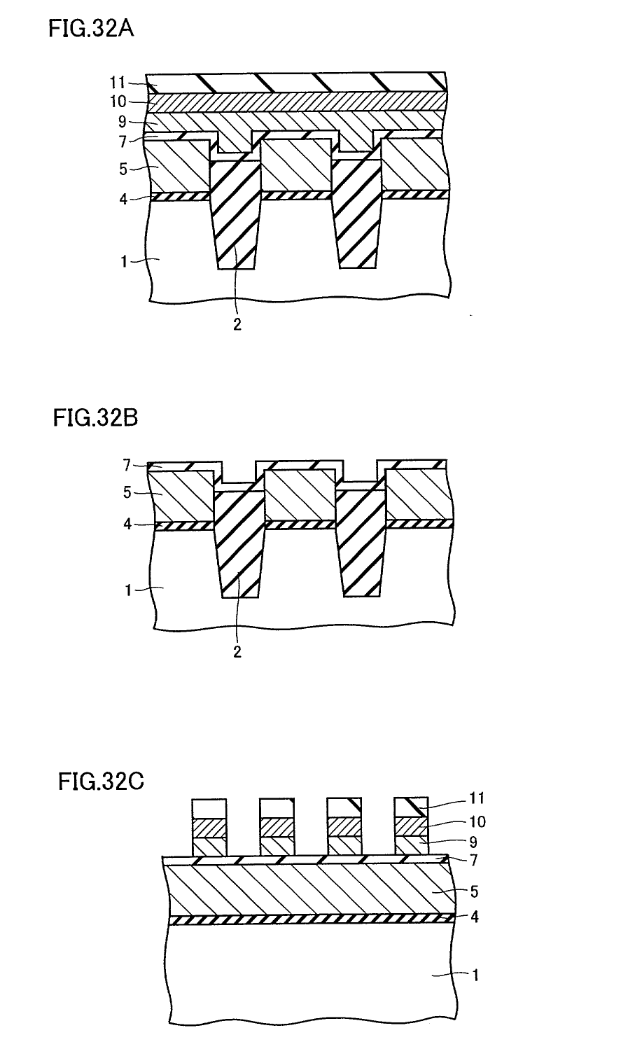

Next, as shown in FIGS. 32A to 32C, using silicon oxide film 11 as a mask, tungsten silicide film 10 and polysilicon film 9 are subjected to dry etching, thereby exposing the surface of ONO film 7.

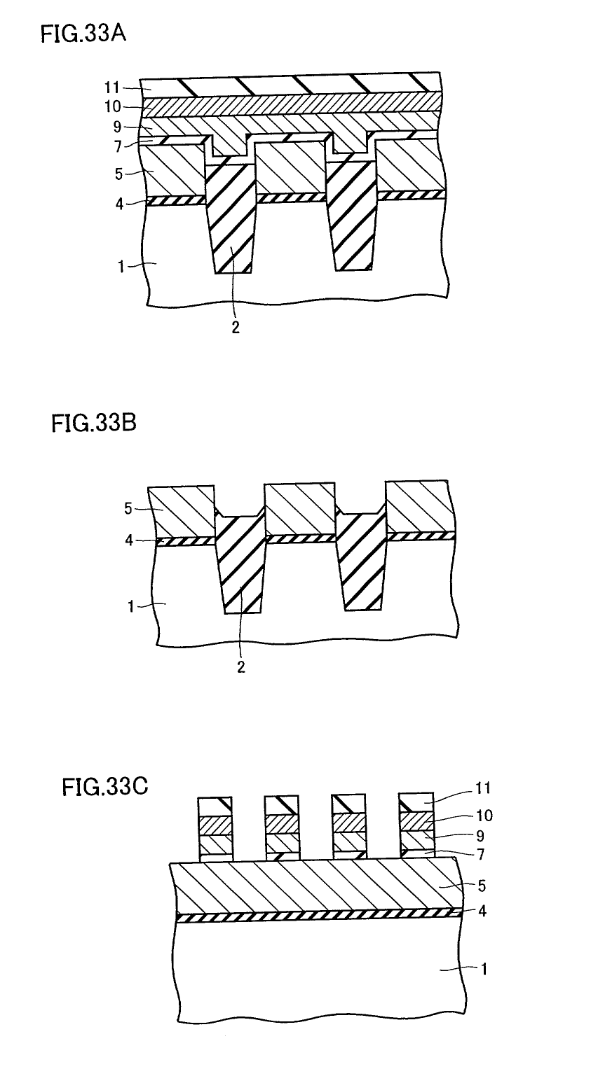

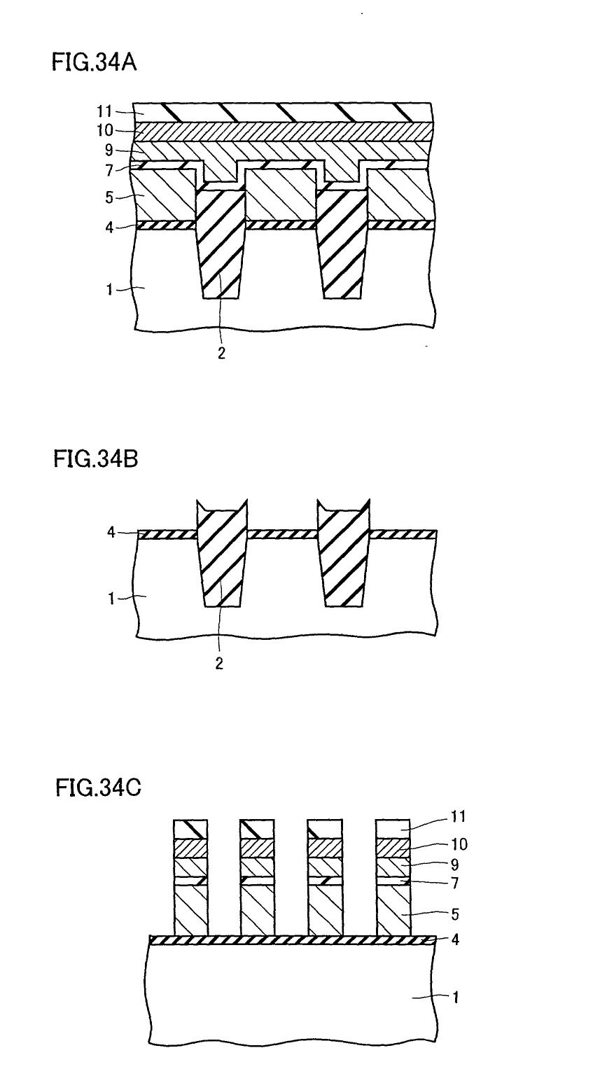

Then, as shown in FIGS. 33A to 33C, exposed ONO film 7 is subjected to anisotropic etching, thereby removing ONO film 7 and exposing amorphous-doped silicon film 5. Next, as shown in FIGS. 34A to 34C, dry etching is conducted to thereby remove amorphous-doped silicon film 5 and to expose tunnel oxide film 4.

Thereafter, wet etching or dry etching by a hydrofluoric acid (HF) is conducted, thereby removing exposed tunnel oxide film 4 and exposing the surface of semiconductor substrate 1.

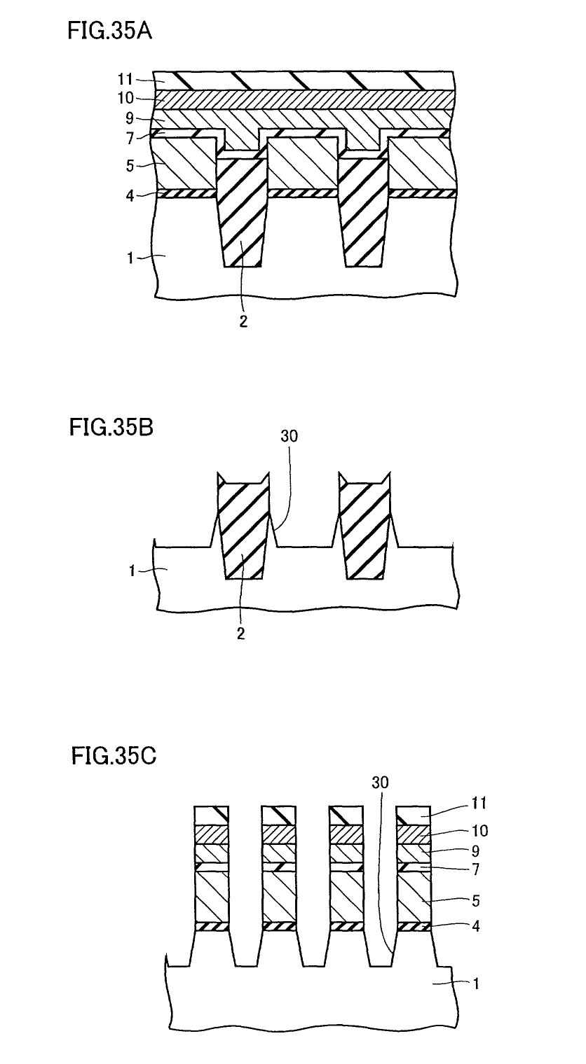

Next, as shown in FIGS. 35A to 35C, the surface of exposed semiconductor substrate 1 is subjected to dry etching, thereby forming recesses 30 each having a depth of about 50 nm. At this moment, if the etching is conducted by, for example, ECR discharge, it is preferable that gas containing chlorine and oxygen is employed as etching gas, pressure is about 0.4 Pa, RF power is about 50 W and microwave power is about 400 W.

This process will be described in more detail. In FIG. 29 to FIGS. 35A to 35C described above, it is the region put between the word lines and put between trench isolation oxide films 2 that is subjected to etching.

By subjecting semiconductor substrate 1 to anisotropic etching using silicon oxide film 11 and trench isolation oxide film 2 formed on each word line as a mask, recesses 30 are formed in a self aligned manner.

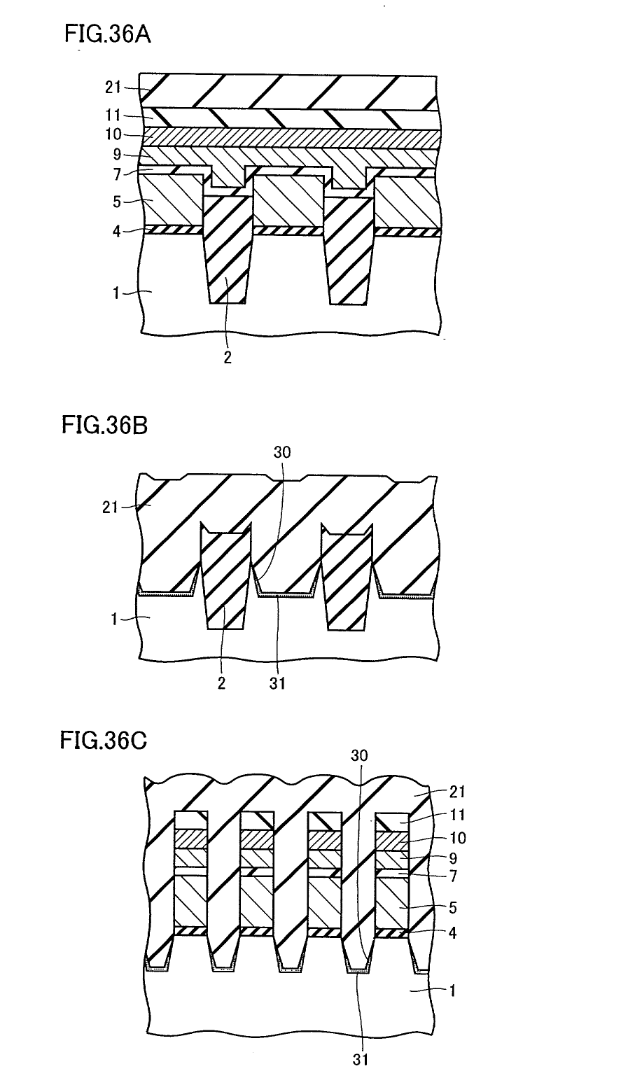

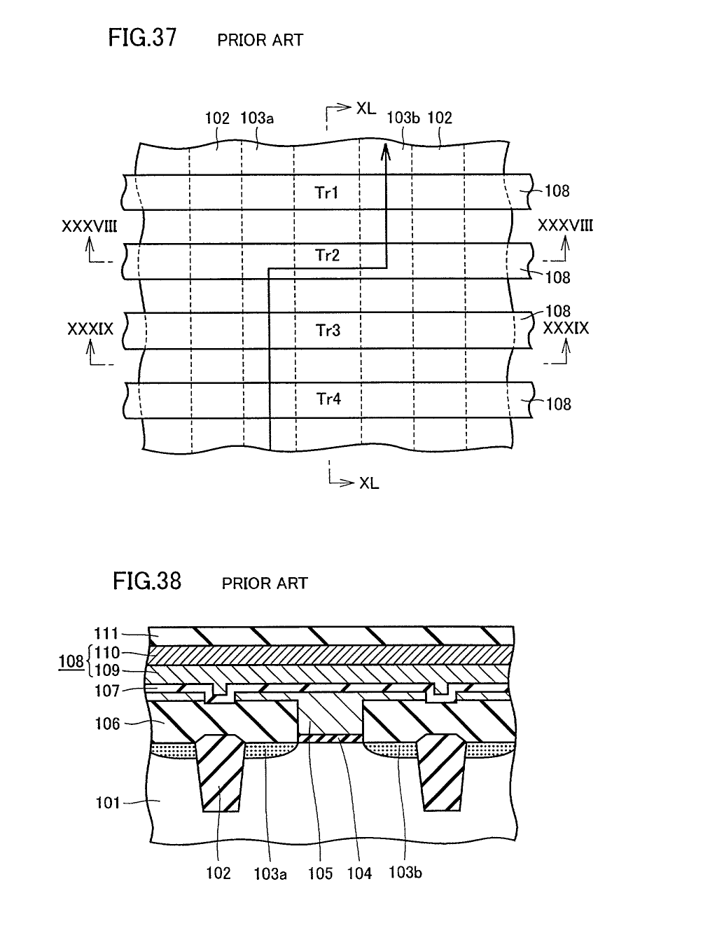

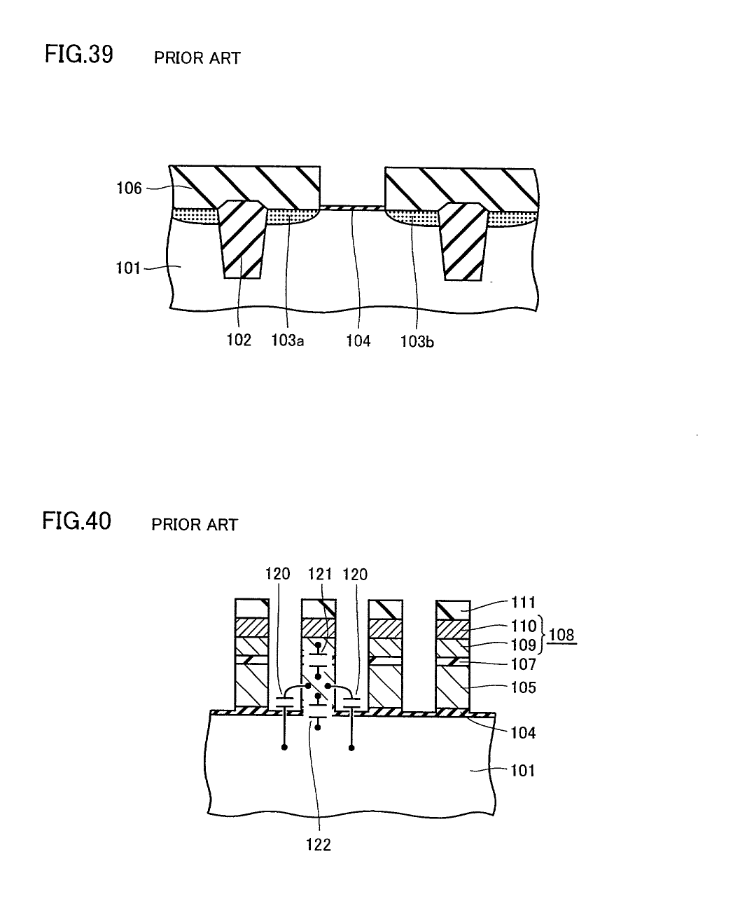

Next, as shown in FIGS. 36A to 36C, arsenic (As) ions are implanted into the surface of recesses 30 with implantation energy of 40 KeV and a dose of 2×10¹⁵/cm², thereby forming impurity regions 31 each serving as a source or a drain. Further, in the peripheral circuit region (not shown), the sources and drains of p type and n type transistors are formed. Then, interlayer insulating film 21 such as a silicon oxide film is formed on semiconductor substrate 1 to cover word lines 8 and the like by, for example, the CVD method. As a result, the main parts of the flash memory shown in FIGS. 21 to 24 are completed.

In this flash memory, recesses 30 are formed and recesses 30 are embedded with interlayer insulating film 21 as already described above, thereby making capacitance Cs 35 between the side surface portion of each word line 8 and the region of semiconductor substrate 1 located below the side surface portion of word line 8 lower. As a result, it is possible to improve the coupling capacitance ratio of the flash memory compared with that of the conventional flash memory and to thereby improve the performance of the flash memory.

In the above-stated manufacturing method of a flash memory, the region of semiconductor substrate 1 put between word lines 8 and put between trench isolation oxide films 2 is subjected to etching using silicon oxide film 11 and trench isolation oxide film 2 as a mask, thereby making it possible to easily form recesses 30 in a self-aligned manner.

The embodiments disclosed in this specification are given for illustrative purposes in all respects and should not be considered to limit the invention.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A nonvolatile semiconductor memory device comprising:
a region formed on a main surface of a semiconductor substrate of a first conductive type, and becoming a predetermined channel;
a first electrode section formed on said region becoming the channel with a first insulating film interposed, and having a bottom surface, side surfaces and an upper surface;
a second electrode section formed on said upper surface of said first electrode section with a second insulating film interposed;
recesses formed in one region and the other region of said semiconductor substrate, sandwiching said region becoming the channel;
a pair of impurity regions of a second conductive type formed at regions sandwiching said region becoming the channel; and
a third insulating film formed on said semiconductor substrate to embed said recesses.

2. The nonvolatile semiconductor memory device according to claim 1, wherein
said pair of impurity regions are formed at said semiconductor substrate in a direction almost orthogonal to a direction coupling said one region and said other region.

3. The nonvolatile semiconductor memory device according to claim 2, wherein
said pair of impurity regions extend along the direction coupling said one region and said other region to sandwich said recesses.

4. The nonvolatile semiconductor memory device according to claim 2, wherein
impurities of the first conductive type are introduced into surfaces of said recesses.

5. The nonvolatile semiconductor memory device according to claim 2, wherein
said recesses are formed deeper than portions on which said pair of impurity regions are located, respectively.

6. The nonvolatile semiconductor memory device according to claim 2, comprising:
a first mask material and a second mask material formed on said pair of impurity regions and said upper surface of said second electrode section, respectively, and each having an insulating property to become a mask for forming said recesses.

7. The nonvolatile semiconductor memory device according to claim 6, wherein
each of said first mask material and said second mask material includes a silicon oxide film.

8. The nonvolatile semiconductor memory device according to claim 1, wherein
said pair of impurity regions are formed on surfaces of said recesses, respectively; and
element isolation insulating films are formed at said semiconductor substrate, in a direction almost orthogonal to a direction coupling said one region and said other region.

9. The nonvolatile semiconductor memory device according to claim 8, comprising:
a mask material formed on said upper surface of said second electrode section and having an insulating property to become a mask for forming said recesses together with said element isolation insulating films.

10. The nonvolatile semiconductor memory device according to claim 9, wherein
each of said mask material and said element isolation insulating film includes a silicon oxide film.

11. A manufacturing method of a nonvolatile semiconductor memory device comprising the steps of:
forming a first conductive layer on a main surface of a semiconductor substrate of a first conductive type and extending in one direction with a first insulating film interposed;
forming a second conductive layer on said first conductive layer with a second insulating film interposed;
forming a predetermined mask member on said second conductive layer;
processing said second conductive layer while using said predetermined mask member as a mask, thereby forming at least two upper electrode sections extending in a direction almost orthogonal to said one direction;
processing further said first conductive layer while using said predetermined mask member as the mask, thereby exposing a surface of said semiconductor substrate and forming lower electrode sections located right below said at least two upper electrode sections, respectively;
forming a pair of impurity regions of a second conductive type at first surface regions of said semiconductor substrate sandwiching said lower electrode sections;
forming recesses at second surface regions of said semiconductor substrate sandwiching said lower electrode sections; and
forming a third insulating film on said semiconductor substrate to embed said recesses.

12. The manufacturing method of a nonvolatile semiconductor memory device according to claim 11, wherein
in the step of forming said pair of impurity regions, said first conductive layer is formed and then said pair of impurity regions are formed along said first conductive layer in said first surface regions sandwiching said first conductive layer;
the manufacturing method comprises a step of forming a fourth insulating film on said pair of impurity regions after forming said pair of impurity regions and before forming said second conductive layer;
in the step of forming said recesses, said recesses are formed by processing said second surface regions put between said two upper electrode sections and put between said pair of impurity regions, respectively while using said predetermined mask member and said fourth insulating film as a mask.

13. The manufacturing method of a nonvolatile semiconductor memory device according to claim 12, comprising:
a step of introducing impurities of the first conductive type into surfaces of said recesses after forming said recesses.

14. The manufacturing method of a nonvolatile semiconductor memory device according to claim 12, wherein
in the step of forming said recesses, said recesses are formed deeper than portions in which said pair of impurity regions are located, respectively.

15. The manufacturing method of a nonvolatile semiconductor memory device according to claim 11, wherein
the manufacturing method comprises a step of, after the step of forming said first conductive layer, forming element isolation insulating films in the one region and the other region of said semiconductor substrate located to put said first conductive layer between said one region and said other region, respectively along a direction in which said first conductive layer extends;
in the step of forming said recesses, said recesses are formed by processing said second surface regions put between said two upper electrode sections and put between said element isolation insulating films while using said predetermined mask member and said element isolating insulating films as the mask; and
in the step of forming said pair of impurity regions, said pair of impurity regions are formed on surfaces of said recesses.
